(19) United States
(12) Patent Application Publication
(10) Pub. No.: US 2024/0357861 A1
(43) Pub. Date: Oct. 24, 2024

(54) DISPLAY PANEL AND ELECTRONIC DEVICE HAVING THE SAME

(71) Applicant: Samsung Display Co., Ltd., Yongin-si (KR)

(72) Inventors: MINJEONG OH, Yongin-si (KR); KIJUNE LEE, Yongin-si (KR); SUNGEUN LEE, Yongin-si (KR); JONGHYUN CHOI, Yongin-si, Gyeonggi-do, (KR)

(21) Appl. No.: 18/425,488

(22) Filed: Jan. 29, 2024

(30) Foreign Application Priority Data
Apr. 20, 2023 (KR) 10-2023-0052102

(51) Int. Cl. H10K 59/121; H10K 59/131; H10K 59/80; H10K 102/00

(52) U.S. Cl. CPC H10K 59/1213; H10K 59/131; H10K 59/8792; H10K 2102/311

(57) ABSTRACT

A display panel includes a light emitting element, and a pixel circuit electrically connected to the light emitting element. The pixel circuit includes a semiconductor pattern layer defining a first semiconductor pattern electrically connected to the light emitting element, and a second semiconductor pattern which is spaced apart from the first semiconductor pattern, a data line on the semiconductor pattern layer and electrically connected to the second semiconductor pattern, and a connection electrode electrically connecting the first semiconductor pattern and the second semiconductor pattern which are spaced apart from each other, to each other. Along a thickness direction of the display panel, the connection electrode is a portion of a metal layer below the semiconductor pattern layer or a portion of a metal layer above the semiconductor pattern layer.

This application claims priority to Korean Patent Application No. 10-2023-0052102, filed on Apr. 20, 2023, and all the benefits accruing therefrom under 35 U.S.C. § 119, the entire contents of which are hereby incorporated by reference.

### BACKGROUND

### (1) Field

The present disclosure herein relates to a display panel, and more particularly, to a flexible display panel.

### (2) Description of the Related Art

Multimedia electronic devices such as televisions, mobile phones, tablets computers, navigation system units, and game consoles may include a display device for displaying images. The display device may include a display panel for generating images, and providing the generated images to outside the display device, such as to a user. The display panel may include a plurality of pixels for generating images and a driver for driving the pixels.

With the development of technology, flexible display devices including flexible display panels are being developed. For example, various flexible display devices which may be deformed into a curved shape, folded, or rolled are being developed. A flexible display device which may be deformed into various shapes is easy to carry, and is capable of improving user convenience.

However, the flexible display panel may be vulnerable to external impact, and some transistors may be damaged by external impacts or stress caused by folding, so that pixels may not operate normally.

### SUMMARY

The present disclosure provides a display panel with improved impact resistance and improved reliability again external impacts or stress.

An embodiment of the invention provides a display panel including a light emitting element, and a pixel circuit electrically connected to the light emitting element. The pixel circuit includes a semiconductor pattern layer including a first semiconductor pattern having one end electrically connected to the light emitting element, and a second semiconductor pattern spaced apart from the first semiconductor pattern on a plane, a data line disposed on the semiconductor pattern layer, and connected to the one end of the second semiconductor pattern, and a connection electrode electrically connecting the other end of the first semiconductor pattern and the other end of the second semiconductor pattern, and including a metal material. The connection electrode is disposed in an upper portion or a lower portion of the semiconductor pattern layer.

In an embodiment, a material included in the connection electrode may be different from a material included in the semiconductor pattern layer.

In an embodiment, the first semiconductor pattern and the second semiconductor pattern may each include polysilicon, and the connection electrode may be composed of a metal material.

In an embodiment, the first semiconductor pattern may include a first source region, a first drain region, and a first channel region disposed between the first source region and the first drain region, and the second semiconductor pattern may include a second source region, a second drain region, and a second channel region disposed between the second source region and the second drain region.

In an embodiment, the connection electrode may electrically connect the first source region of the first semiconductor pattern and the second drain region of the second semiconductor pattern.

In an embodiment, the first drain region of the first semiconductor pattern may be electrically connected to the light emitting element, and the second source region of the second semiconductor pattern may be electrically connected to the data line.

In an embodiment, the pixel circuit may include a driving transistor and a switching transistor. The driving transistor may include a first gate electrode overlapping the first semiconductor pattern and the first channel region and disposed on the first semiconductor pattern, and the switching transistor may include a second gate electrode overlapping the second semiconductor pattern and the second channel region and disposed on the second semiconductor pattern.

In an embodiment, the pixel circuit may further include a first insulation layer disposed in a lower portion of the semiconductor pattern layer, and a buffer layer disposed in a lower portion of the first insulation layer, along a thickness direction of the display panel. The connection electrode may be disposed on the buffer layer.

In an embodiment, the pixel circuit may further include a light blocking pattern disposed on the same layer as the connection electrode.

In an embodiment, the connection electrode may include molybdenum.

In an embodiment, a first contact-hole and a second contact-hole penetrating at least a portion of the buffer layer may be disposed in the pixel circuit. The first semiconductor pattern and the connection electrode may be connected through the first contact-hole, and the second semiconductor pattern and the connection electrode may be connected through the second contact-hole.

In an embodiment, the pixel circuit may further include a second insulation layer covering the first semiconductor pattern and the second semiconductor pattern and disposed on the semiconductor pattern layer, and a third insulation layer disposed on the second insulation layer. The connection electrode may be disposed on the third insulation layer.

In an embodiment, a third contact-hole and a fourth contact-hole penetrating at least a portion of the second insulation layer and the third insulation layer may be disposed in the pixel circuit. The connection electrode and the first transistor pattern may be connected through the third contact-hole, and the connection electrode and the second transistor pattern may be connected through the fourth contact-hole.

In an embodiment, the connection electrode may include aluminum, or titanium.

In an embodiment, the clastic modulus of the connection electrode may be about 50 gigapascals (GPa) to about 130 GPa.

In an embodiment, the clastic modulus of the connection electrode may be lower than the clastic modulus of the semiconductor pattern layer.

In an embodiment, the semiconductor pattern layer may further include a third semiconductor pattern formed as a single body with the first semiconductor pattern and connected to the first semiconductor pattern. The third semiconductor pattern may be spaced apart from the second semiconductor pattern on a plane.

In an embodiment, the light emitting element may include a first electrode, a plurality of organic layers disposed on the first electrode and including a light emitting layer, and a second electrode disposed on the plurality of organic layers. One end of the third semiconductor pattern may be electrically connected to the first electrode and the other end of the third semiconductor pattern may be electrically connected to the first semiconductor pattern.

In an embodiment of the invention, a display panel includes a light emitting element, and a pixel circuit electrically connected to the light emitting element. The pixel circuit includes a buffer layer, a first insulation layer disposed on the buffer layer, a first semiconductor pattern disposed on the first insulation layer, a second semiconductor pattern spaced apart from the first semiconductor pattern on the first insulation layer on a plane and connected to the first semiconductor pattern by a connection electrode, a second insulation layer disposed on the first insulation layer and covering the first semiconductor pattern and the second semiconductor pattern, a first gate electrode and a second gate electrode disposed on the second insulation layer, and a third insulation layer disposed on the second insulation layer and covering the first gate electrode and the second gate electrode. The first semiconductor pattern and the second semiconductor pattern each include polysilicon, and the connection electrode includes a metal material.

In an embodiment, the first semiconductor pattern and the second semiconductor pattern and the connection electrode may not be disposed on the same layer, that is, may be in different material layers from each other.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view of a display device according to an embodiment of the invention;

FIG. 2A and FIG. 2B are perspective views illustrating a folded state of the display device illustrated in FIG. 1;

FIG. 3 is a cross-sectional view of a display panel according to an embodiment of the invention;

FIG. 4 is a plan view of a display panel according to an embodiment of the invention;

FIG. 5 is an equivalent circuit diagram of a pixel according to an embodiment of the invention;

FIG. 6 is a cross-sectional view of a display panel according to an embodiment of the invention;

FIG. 7A to FIG. 7G are plan views of pattern layers of a pixel according to an embodiment of the invention;

FIG. 7H is an enlarged cross-sectional view showing a partial configuration of a circuit element layer according to an embodiment of the invention;

FIG. 8A to FIG. 8C are plan views of pattern layers of a pixel according to an embodiment of the invention; and

FIG. 8D is an enlarged cross-sectional view showing a partial configuration of a circuit element layer according to another embodiment of the invention.

### DETAILED DESCRIPTION

The invention may be modified in many alternate forms, and thus specific embodiments will be exemplified in the drawings and described in detail. It should be understood, however, that it is not intended to limit the invention to the particular forms disclosed, but rather, is intended to cover all modifications, equivalents, and alternatives falling within the spirit and scope of the invention.

In the present disclosure, when an element (or a region, a layer, a portion, etc.) is referred to as being related to another element such as being “on,” “connected to,” or “coupled to” another element, it means that the element may be directly disposed on/connected to/coupled to the other element, or that a third element may be disposed therebetween. In contrast, when an element (or a region, a layer, a portion, etc.) is referred to as being related to another element such as being “directly on,” “directly connected to,” or “directly coupled to” another element, it means that no third element is disposed therebetween.

Like reference numerals refer to like elements. Also, in the drawings, the thickness, the ratio, and the dimensions of elements are exaggerated for an effective description of technical contents.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” The term “and/or” includes any and all combinations of one or more of which associated elements may define.

It will be understood that, although the terms “first,” “second,” etc. may be used herein to describe various elements, these elements should not be limited by these terms. These terms are only used to distinguish one element from another. For example, a first element may be referred to as a second element, and a second element may also be referred to as a first element in a similar manner without departing the scope of rights of the present invention.

The terms of a singular form may include plural forms unless the context clearly indicates otherwise. For example, within the Figures and the text of the disclosure, a reference number indicating a singular form of an element may also be used to reference a plurality of the singular element.

In addition, terms such as “below,” “lower,” “above,” “upper,” and the like are used to describe the relationship of the elements shown in the drawings. The terms are used as a relative concept and are described with reference to the direction indicated in the drawings.

It should be understood that the term “comprise,” or “have” is intended to specify the presence of stated features, integers, steps, operations, elements, components, or combinations thereof in the disclosure, but do not preclude the presence or addition of one or more other features, integers, steps, operations, elements, components, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which the present invention pertains. It is also to be understood that terms such as terms defined in commonly used dictionaries should be interpreted as having meanings consistent with the meanings in the context of the related art, and should not be interpreted in too ideal a sense or an overly formal sense unless explicitly defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a display panel DP according to an embodiment of the invention will be described with reference to the accompanying drawings.

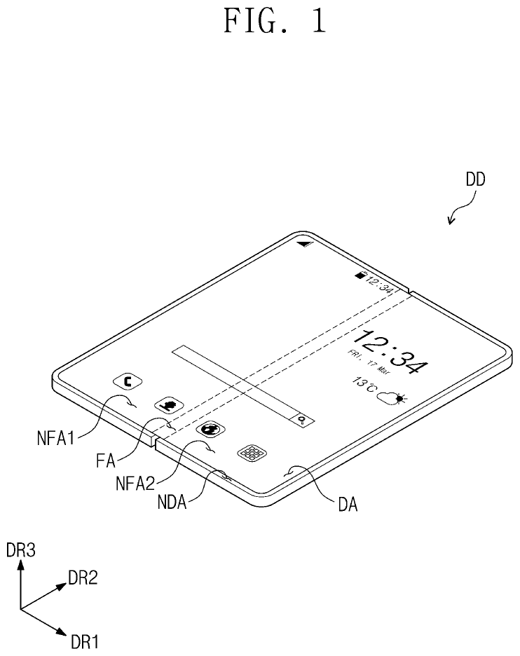

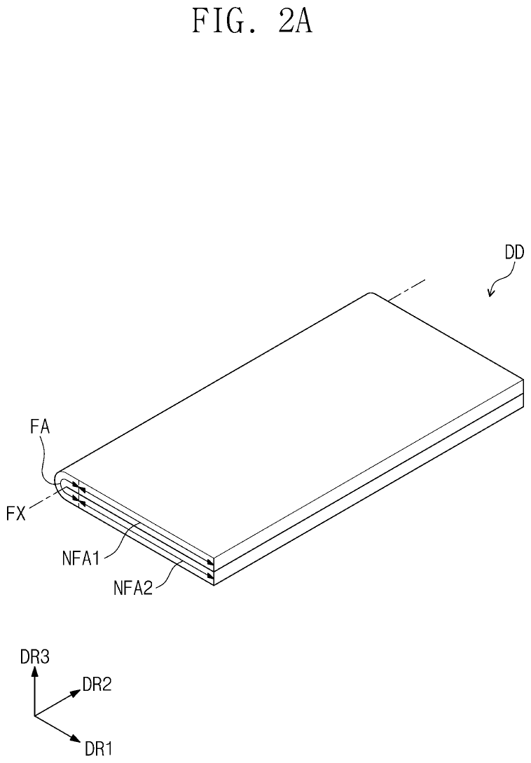

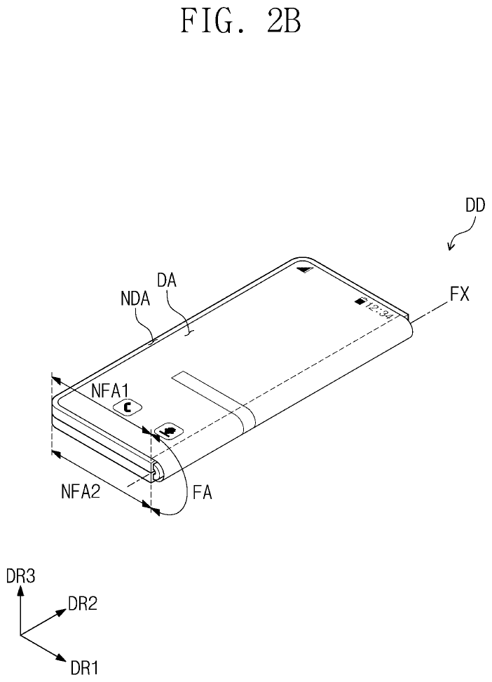

FIG. 1 is a perspective view of a display device DD according to an embodiment of the invention. FIG. 2A and FIG. 2B are perspective views illustrating a folded state of the display device DD illustrated in FIG. 1.

The display device DD may be a device (e.g., an electronic device) which is activated by an electrical signal and displays images. The display device DD may include various embodiments. For example, the display device DD may be a large-sized device such as a television and an external billboard, as well as a small-and-medium-sized device such as a monitor, a mobile phone, a tablet computer, a navigation system unit, and a game console. The embodiments of the display device DD are only exemplary, and are not limited to any one thereof as long as it does not depart from the invention. In the present embodiment, a mobile phone is illustrated as an example of the display device DD.

Referring to FIG. 1, the display device DD may have a rectangular shape which has long sides extended in a first direction DR1 on a plane and short sides extended in a second direction DR2 intersecting the first direction DR1. However, the invention is not limited thereto, and the display device DD may have various planar shapes on a plane, such as a circular shape, and a polygonal shape other than the rectangular shape.

The display device DD may be flexible. Being “flexible” refers to having properties of being able to be bent (e.g., bendable), which may include from a foldable structure of being completely folded to a structure of being able to be bent to a degree of a few nanometers. For example, the flexible display device DD may include a curvable display device, a rollable display device, a slidable display device, or a foldable display device. In the present embodiment, as an example of the flexible display device DD, a foldable display device is illustrated.

As illustrated in FIG. 1, the display device DD which is unfolded or flat (e.g., in an unfolded state) may display an image in (or along) a third direction DR3, through a display surface parallel to a plane defined by the first direction DR1 and the second direction DR2 crossing each other. The third direction DR3 may be defined as a direction substantially perpendicularly intersecting a plane defined by the first direction DR1 and the second direction DR2.

The front surface (or upper surface) and the rear surface (or lower surface) of members constituting the display device DD may oppose each other in the third direction DR3, and a normal direction of each of the front surface and the rear surface may be substantially parallel to the third direction DR3. A separation distance between the front surface and the rear surface which is defined along the third direction DR3 may correspond to the thickness of a member (or unit). A thickness of the display device DD and various layers or components thereof may be defined along the third direction DR3 (e.g., a thickness direction).

In the present disclosure, “on a plane” may be defined as a state viewed in the third direction DR3 (e.g., in a plan view). In the present disclosure, “on a cross-section” may be defined as a state viewed in the first direction DR1 or the second direction DR2. Meanwhile, directions indicated by the first to third directions DR1, DR2, and DR3 are a relative concept, and may be converted to different directions.

The front surface of the display device DD may be divided into a display region DA and a non-display region NDA. The display device DD may display an image through the display region DA, and the image may be visually recognized through display region DA from outside of the display device DD, such as by a user. The image may include both a moving image and a still image. In FIG. 1, as an example of the image, application icons and a watch window are illustrated.

The non-display region NDA may be a region in which an image is not displayed. The non-display region NDA may be adjacent to the display region DA. For example, the non-display region NDA may surround the display region DA on a plane. However, the embodiment of the invention is not limited thereto, and the non-display region NDA may be adjacent to only one side of the display region DA, or may be disposed on or along a side surface of the display device DD which is extended bent or curved from the front surface, not the front surface, of the display device DD. The non-display region NDA may correspond to a region in which a pattern or layer such as a print layer having a predetermined color is formed, and may define the edge of the display device DD in the plan view.

The display device DD may include a folding region FA and a non-folding region such as one or more among non-folding regions NFA1 and NFA2. The non-folding regions NFA1 and NFA2 may include a first non-folding region NFA1 and a second non-folding region NFA2. The non-folding regions NFA1 and NFA2 may be arranged along the first direction DR1 with the folding region FA interposed therebetween.

The folding region FA may be a region which is flat or disposed in a single plane, or bent with a predetermined curvature, depending on a folding operation. That is, the folding region FA may be a region at which the display device DD and/or various components or layers thereof are curvable, foldable, bendable, rollable, etc. As illustrated in FIG. 1, when the display device DD is unfolded or flat (e.g., in a non-folded state), the folding region FA may be in a flat state. The non-folding regions NFA1 and NFA2 may be regions which remain flat in both the folded and non-folded states of the display device DD.

The display device DD may be foldable about a folding axis FX extended along one direction. Referring to FIG. 2A and FIG. 2B, a folding axis FX may be extended along the second direction DR2 parallel to the long sides of the display device DD. However, the extension direction of the folding axis FX is not limited thereto, and the folding axis FX may be extended along a direction parallel to the short sides of the display device DD. In this case, non-folding regions may be arranged along the second direction DR2 with a folding region FA interposed therebetween.

The display device DD may be in-folded or out-folded about the folding axis FX. The display device DD may be folded to be in one of in-folded and out-folded states, or may be mutually transformed from being in-folded to being out-folded. FIG. 2A exemplarily illustrates the display device DD in an in-folded state, and FIG. 2B exemplarily illustrates the display device DD in an out-folded state.

Referring to FIG. 2A, in an embodiment, the folding axis FX may be defined to face the front surface of the display device DD. In the in-folded state, a display surface at the front surface and corresponding to the folding region FA may be folded while forming a concavely curved surface facing the folding axis FX. In the in-folded state, portions of the display surface corresponding to the first and second non-folding regions NFA1 and NFA2 of the display device DD may overlap along the thickness direction while facing each other. In the in-folded state, the front surface of the display device DD may not be exposed to the outside of the display device DD.

Referring to FIG. 2B, in an embodiment, the folding axis FX may be defined to face the rear surface of the display device DD which is opposite to the front surface. In the out-folded state, a display surface corresponding to the folding region FA may be folded while forming a convexly curved surface opposing the folding axis FX. In the out-folded state, portions of the display surface corresponding to the first and second non-folding regions NFA1 and NFA2 of the display device DD may be exposed to the outside of the display device DD.

In the out-folded state, the display surfaces corresponding to the first and second non-folding regions NFA1 and NFA2 may overlap on a plane and display images in directions opposite to each other. In the out-folded state, the display region DA of the display device DD may be exposed to the outside and display an image, and the displayed image may be visually recognized from outside the display device DD, such as by a user, in a folded state of the display device DD.

In the present embodiment, the display device DD is illustrated as being out-foldable and in-foldable about one folding axis FX, but the number of folding axes FX defined in the display device DD is not limited thereto, and the display device DD may be foldable around a plurality of folding axes. The folding operation of the display device DD is not limited to the illustrated embodiment, and may be designed in various forms.

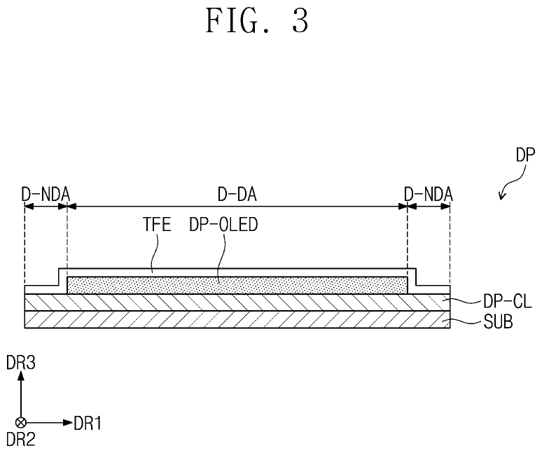

FIG. 3 is a cross-sectional view of a display panel DP according to an embodiment of the invention.

The display panel DP may be included in the display device DD (see FIG. 1). The display panel DP according to an embodiment may be a light emitting-type display panel, but is not particularly limited. For example, the display panel DP may be an organic light emitting display panel, an inorganic light emitting display panel, or a quantum dot light emitting display panel. Hereinafter, the display panel DP will be described as an organic light emitting display panel.

Referring to FIG. 3, the display panel DP may include a base substrate SUB, a circuit element layer DP-CL, a display element layer DP-OLED, and an encapsulation layer TFE.

The base substrate SUB may provide a base surface on which the circuit element layer DP-CL is disposed. The base substrate SUB may include a display region D-DA and a non-display region D-NDA. The display region D-DA and the non-display region D-NDA of the base substrate SUB may respectively correspond to the display region DA (see FIG. 1) and the non-display region NDA (see FIG. 1) of the display device DD (see FIG. 1).

The base substrate SUB may include a flexible polymer material. For example, the base substrate SUB may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, a perylene-based resin and a polyimide resin. However, the material of the base substrate SUB is not limited thereto.

The circuit element layer DP-CL may be disposed on the base substrate SUB. The circuit element layer DP-CL may include at least one insulation layer, a pixel driving circuit PDC, signal lines, and signal pads PD, which will be described later. The circuit element layer DP-CL may be formed or provided by forming an insulation layer, a semiconductor layer, and a conductive layer on the base substrate SUB through a coating or a deposition process, and then patterning the insulation layer, the semiconductor layer, and the conductive layer through a photolithography process.

The display element layer DP-OLED may be disposed on the circuit element layer DP-CL. The display element layer DP-OLED may generate and/or emit light and may include light emitting elements OLED disposed overlapping the display region D-DA. The light emitting elements OLED of the display element layer DP-OLED may be electrically connected to a driving circuit of the circuit element layer DP-CL, and may output light through the display region DA in response to a driving signal as an electrical signal.

The encapsulation layer TFE may be disposed on the display element layer DP-OLED to encapsulate the light emitting elements OLED on the base substrate SUB. The encapsulation layer TFE may include a plurality of thin films. The thin films of the encapsulation layer TFE may be disposed to improve optical efficiency of the light emitting devices, or to protect the light emitting devices.

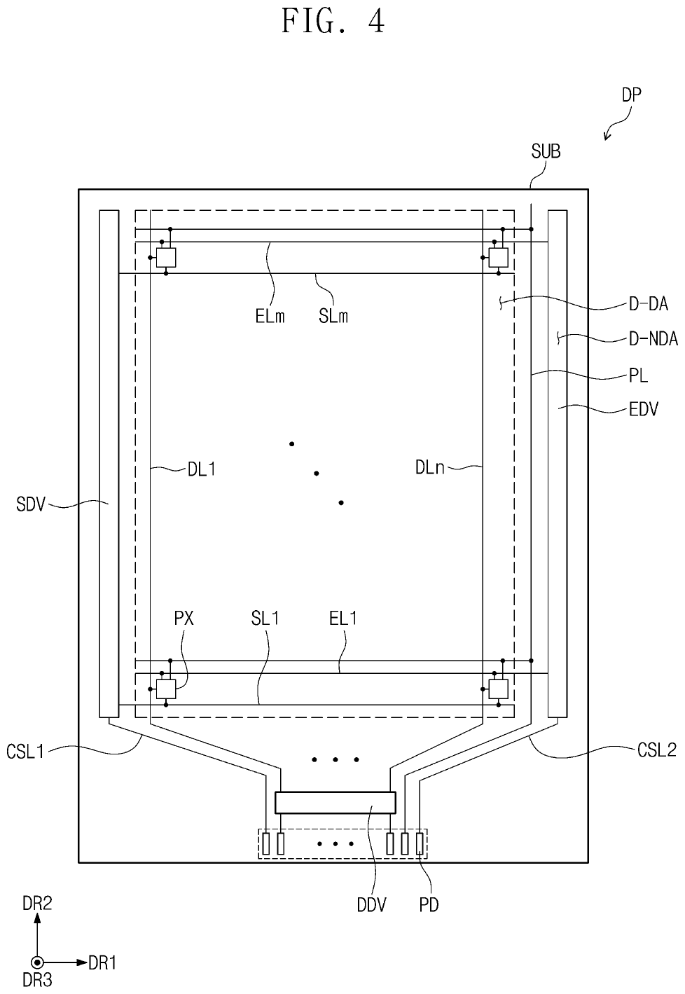

FIG. 4 is a plan view of the display panel DP according to an embodiment of the invention.

Referring to FIG. 4, the display panel DP may include pixels PX disposed in the display region D-DA and signal lines which are electrically connected to the pixels PX. The display panel DP may include a scan driver SDV, a data driver DDV, a light emission driver EDV, and a signal pad PD provided in plural including signal pads PD, which are disposed in the non-display region D-NDA.

Each of the pixels PX may include a light emitting element OLED, transistors (e.g., a switching transistor, a driving transistor, etc.) electrically connected to the light emitting element OLED, and a pixel driving circuit PDC including a capacitor CAP. Each of the pixels PX may emit light in response to an electrical signal applied to the pixels PX.

The signal lines may include scan lines SL1 to SLm, data lines DL1 to DLn, light emission lines EL1 to ELm, a first control line CSL1, a second control line CSL2, and a power line PL. Here, ‘m’ and ‘n’ represent natural numbers of 1 or greater.

Each of the pixels PX may be connected to a corresponding scan line among the scan lines SL1 to SLm, a corresponding data line among the data lines DL1 to DLn, and a corresponding light emission line among the light emission lines EL1 to ELm. Meanwhile, depending on the configuration of the pixel driving circuit PDC of the pixels PX, more types of signal lines may be provided in the display panel DP.

The scan driver SDV and the light emission driver EDV may be disposed in the non-display region D-NDA adjacent to long sides of the display panel DP. The data driver DDV may be disposed adjacent to a lower end of the display panel DP on a plane.

The scan lines SL1 to SLm may be extended in the first direction DR1 to be electrically connected to the scan driver SDV. The light emission lines EL1 to ELm may be extended in the first direction DR1 to be electrically connected to the light emission driver EDV. The scan lines SL1 to SLm and the light emission lines EL1 to ELm may be arranged spaced apart from each other in (or along) the second direction DR2. The data lines DL1 to DLn may intersect the scan lines SL1 to SLm and the light emission lines EL1 to ELm on a plane. The data lines DL1 to DLn may be extended in the second direction DR2 to be electrically connected to the data driver DDV.

The power line PL may be electrically connected to the pixels PX to provide an electrical voltage applied to the power line PL, to the pixels PX. The power line PL may include a portion extended in the first direction DR1 and a portion extended in the second direction DR2. The portion extended in the first direction DR1 of the power line PL may be extended on the display region D-DA to be connected to the pixels PX, and the portion extended in the second direction DR2 of the power line PL may be extended on the non-display region D-NDA to be connected to a signal pad PD. The portion extended in the first direction DR1 and the portion extended in the second direction DR2 of the power line PL may be in different layers and connected to each other through a contact-hole, or may have a shape of a single body as respective portions of the same layer.

The first control line CSL1 may be electrically connected to the scan driver SDV. The second control line CSL2 may be electrically connected to the light emission driver EDV.

The signal pads PD may be arranged along the first direction DR1, along an edge of the display panel DP which corresponds to an edge of the base substrate SUB. The signal pads PD may be terminals or pads at which the display panel DP is electrically connected to an external component such as a circuit board. The external component such as the circuit board may include a timing controller for controlling the operation of the scan driver SDV, the data driver DDV, and the light emission driver EDV, and a voltage generator for generating voltages required for driving the display panel DP.

Each of the signal pads PD may be connected to a corresponding signal line. For example, the first control line CSL1, the second control line CSL2, the power line PL, and the data lines DL1 to DLn may be variously connected to the signal pads PD. The data lines DL1 to DLn may be electrically connected to a corresponding signal pad PD through the data driver DDV.

The scan driver SDV may generate scan signals as electrical signals in response to a scan control signal as an electrical signal. The scan signals may be applied to the pixels PX through the scan lines SL1 to SLm. The data driver DDV may generate data voltages corresponding to image signals in response to a data control signal. The data voltages may be applied to the pixels PX through the data lines DL1 to DLn. The light emission driver EDV may generate light emission signals in response to a light emission control signal. The light emission signals may be applied to the pixels PX through the light emission lines EL1 to ELm.

The pixels PX may be provided with the data voltages in response to the scan signals. The pixels PX may display an image by emitting light of luminance corresponding to the data voltages in response to the light emission signals. The light emission duration of the pixels PX may be controlled by the light emission signals. As a result, the display panel DP may output an image in the display region D-DA through the pixels PX.

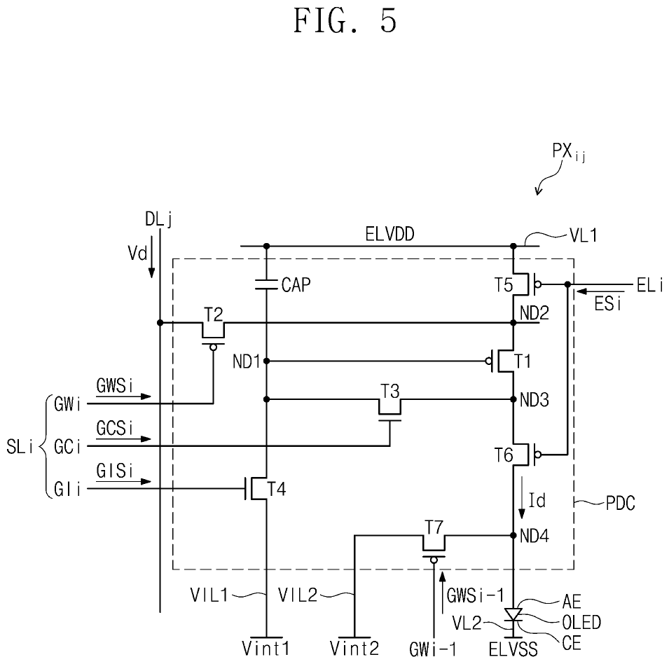

FIG. 5 is a view illustrating an equivalent circuit of a pixel PXij according to an embodiment of the invention. Illustratively, in FIG. 5, a pixel PXij connected to an i-th scan line SLi, an i-th light emission line ELi, and a j-th data line DLj is exemplarily illustrated. Here, ‘i’ and ‘j’ represent natural numbers.

Referring to FIG. 5, the pixel PXij may include a light emitting element OLED, and a pixel driving circuit PDC electrically connected the light emitting element OLED. The pixel driving circuit PDC may include transistors T1 to T7 and a capacitor CAP. The transistors T1 to T7 and the capacitor CAP may control the amount of electrical current flowing through the light emitting element OLED, and the light emitting element OLED may generate light having a predetermined luminance according to the amount of the electrical current provided thereto.

The i-th scan line SLi may include i-th first to third scan lines GWi, GCi, and Gli. A first scan line GWi receiving an i-th write scan signal GWSi may be defined as an i-th write scan line GWi. A second scan line GCi receiving an i-th compensation scan signal GCSi may be defined as a compensation scan line GCi. A third scan line Gli receiving an i-th initialization scan signal GISi may be defined as an initialization scan line Gli.

The transistors T1 to T7 may include first to seventh transistors T1 to T7. The first to seventh transistors T1 to T7 may each include a source electrode, a drain electrode, and a gate electrode. Hereinafter, the source electrode may be referred to as a source, the drain electrode may be referred to as a drain, and the gate electrode may be referred to as a gate.

Meanwhile, in the present disclosure, “being electrically connected (or connected) between a transistor and a signal line, or between a transistor and a transistor” means that “an electrode of the transistor may have a shape of a single body with the signal line, or may be connected through a connection electrode.”

The first to seventh transistors T1 to T7 may be a transistor having an oxide semiconductor layer, or a transistor having a low-temperature polycrystalline silicon (LTPS) semiconductor layer. The first to eighth transistors T1 to T7 may each be an N-type transistor or P-type transistor. For example, the first, second, fifth, sixth, and seventh transistors T1, T2, T5, T6, and T7 may each be a PMOS transistor having a LTPS semiconductor layer, and the third and fourth transistors T3 and T4 may each be an NMOS transistor having an oxide semiconductor layer. However, the embodiments of the transistors T1 to T7 are not limited thereto. In addition, although the pixel driving circuit PDC including the seven transistors T1 to T7 is exemplarily illustrated, the number of transistors included in the pixel driving circuit PDC is not limited thereto.

The light emitting element OLED may be defined as an organic light emitting element. The light emitting element OLED may include a first electrode AE and a second electrode CE. For example, the first electrode AE may be an anode and the second electrode CE may be a cathode. The first electrode AE of the light emitting element OLED may be electrically connected to a first voltage line VL1 receiving a first driving voltage ELVDD. The second electrode CE of the light emitting element OLED may be electrically connected to a second voltage line VL2 receiving a second driving voltage ELVSS.

The first transistor T1 may be electrically connected between the first voltage line VL1 receiving the first driving voltage ELVDD and the light emitting element OLED. The first transistor T1 may include a source connected to a second node ND2, a drain connected to a third node ND3, and a gate connected to a first node ND1. The first transistor T1 may be turned on by a voltage of the first node ND1. The first transistor T1 may receive a data voltage Vd transmitted by the data line DLj according to a switching operation of the second transistor T2 and supply a driving current Id to the light emitting element OLED. In the present embodiment, the first transistor T1 may be defined as a driving transistor.

The second transistor T2 may be electrically connected between the data line DLj and the first transistor T1. The second transistor T2 may include a source connected to the data line DLj, a drain connected to the second node ND2, and a gate connected to the first scan line GWi. The second transistor T2 and the first transistor T1 may be connected through the second node ND2. The second transistor T2 may be turned on by the write scan signal GWSi applied through the first scan line GWi. The data voltage Vd applied to the data line DLj by the turned-on second transistor T2 may be transmitted to the source of the first transistor T1. In the present embodiment, the second transistor T2 may be defined as a switching transistor.

The third transistor T3 may be connected between the fourth transistor T4 and the first transistor T1. The third transistor T3 may include a source connected to the first node ND1, a drain connected to the third node ND3, and a gate connected to the second scan line GCi. The third transistor T3 and the first transistor T1 may be connected through the third node ND3. The third transistor T3 may be turned on by the compensation scan signal GCSi applied through the second scan line GCi. The gate of the first transistor T1 and the drain of the first transistor T1 may be electrically connected to each other by the turned-on third transistor T3, and may diode-connect the first transistor T1. In the present embodiment, the third transistor T3 may be defined as a compensation transistor.

The fourth transistor T4 may be electrically connected between a first initialization line VIL1 receiving a first initialization voltage Vint1 and the third transistor T3. The fourth transistor T4 may include a source connected to the first initialization line VIL1, a drain connected to the first node ND1, and a gate connected to the third scan line Gli. The fourth transistor T4 may be turned on by the initialization scan signal GISi applied through the third scan line Gli. The first initialization voltage Vint1 may be transmitted to the first node ND1 by the turned-on fourth transistor T4, and the potential of the gate of the first transistor T1 may be initialized. In the present embodiment, the fourth transistor T4 may be defined as an initialization transistor.

The fifth transistor T5 may be electrically connected between the first voltage line VL1 receiving the first driving voltage ELVDD and the first transistor T1. The fifth transistor T5 may include a source connected to the first voltage line VL1, a drain connected to the second node ND2, and a gate connected to the light emission line ELi.

The sixth transistor T6 may be electrically connected between the first transistor T1 and the light emitting element OLED. The sixth transistor T6 may include a source connected to the third node ND3, a drain connected to the first electrode AE of the light emitting element OLED, and a gate connected to the light emission line ELi.

The fifth transistor T5 and the sixth transistor T6 may be turned on by a light emission signal ESi applied through the light emission line ELi. The light emission duration of the light emitting element OLED may be controlled by the light emission signal ESi. When the fifth transistor T5 and the sixth transistor T6 are turned on, the driving current Id may be generated in accordance to a voltage difference between a gate voltage of the gate of the first transistor T1 and the first driving voltage ELVDD, and the driving current Id is supplied to the light emitting element OLED through the sixth transistor T6, so that the light emitting element OLED may emit light. In the present embodiment, the fifth transistor T5 and the sixth transistor T6 may be defined as light emission control transistors.

The seventh transistor T7 may be electrically connected between the sixth transistor T6 and a second initialization voltage line VIL2 receiving a second initialization voltage Vint2. The seventh transistor T7 may include a source connected to the fourth node ND4, a drain connected to the second initialization voltage line VIL2, and a gate connected to an i−1-th write scan line GWi−1. The gate of the seventh transistor T7 may be connected to the i−1-th write scan line GWi−1, which is a write scan line of the previous stage of the i-th write scan line GWi. However, the embodiment of the invention is not limited thereto, and the gate of the seventh transistor T7 may be electrically connected to a separate fourth scan line.

The seventh transistor T7 may be turned on by an i−1-th write scan signal GWSi−1 applied through the i−1-th write scan line GWi−1. By the turned-on seventh transistor T7, the second initialization voltage Vint2 may be transmitted to the fourth node ND4. The second initialization voltage Vint2 may have the same level as the first initialization voltage Vint1, without being limited thereto, may have a different level from the first initialization voltage Vint1. In the present embodiment, the seventh transistor T7 may be defined as an initialization transistor.

The seventh transistor T7 may improve the capability of the pixel PXij expressing black. A portion of the driving current Id may exit as a bypass current through the seventh transistor T7 by the seventh transistor T7. When a black image is displayed, a current reduced by the amount of current of the bypass current exited from the driving current Id through the seventh transistor T7 may be provided to the light emitting element OLED, so that the black image may be clearly displayed. That is, an accurate black luminance image may be implemented through the seventh transistor T7, so that the contrast ratio of the display device DD (see FIG. 1) may be improved.

The capacitor CAP may include a first capacitor electrode receiving the first driving voltage ELVDD and a second capacitor electrode connected to the first node ND1. In the capacitor CAP, charges corresponding to a voltage difference between the first capacitor electrode and the second capacitor electrode may be stored. When the fifth transistor T5 and the sixth transistor T6 are turned on, the amount of current flowing through the first transistor T1 may be determined in accordance with the voltage stored in the capacitor CAP.

Meanwhile, the configuration of the pixel driving circuit PDC illustrated in FIG. 5 is only exemplary, and the configuration of the pixel driving circuit PDC is not limited thereto, and may be changed and implemented.

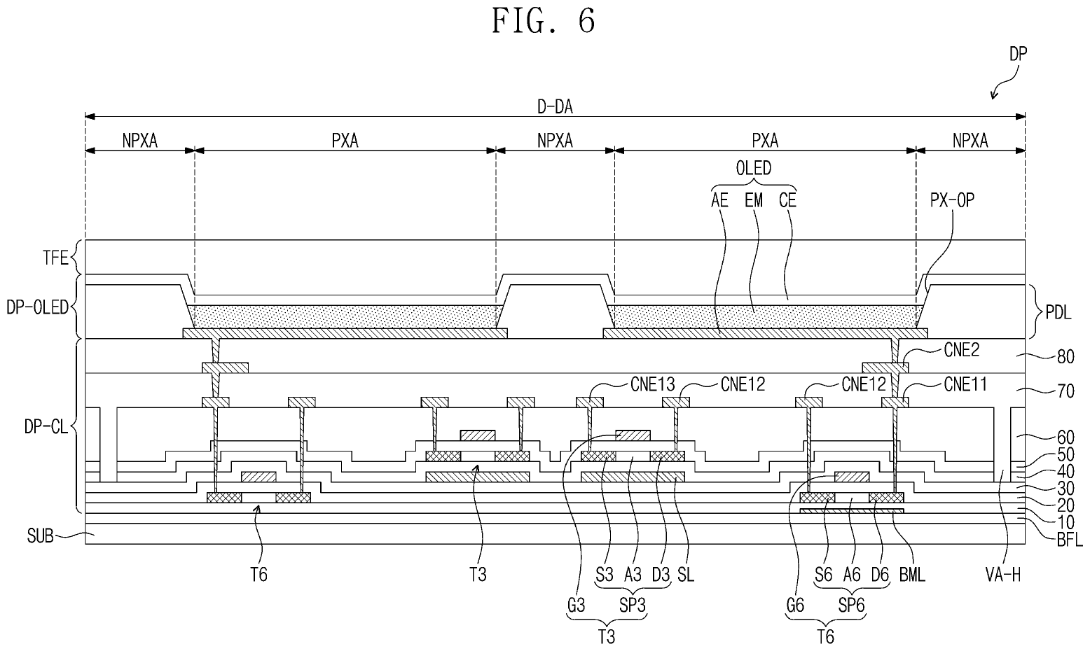

FIG. 6 is a cross-sectional view of a display panel DP according to an embodiment of the invention. FIG. 6 exemplarily illustrates light emitting elements OLED and some transistors T3 and T6 of pixel driving circuits PDC (see FIG. 5) which are respectively connected to the light emitting elements OLED. The aforementioned description may be applied to components of the display panel DP illustrated in FIG. 6.

Referring to FIG. 6, the display panel DP may include a base substrate SUB, a circuit element layer DP-CL, a display element layer DP-OLED, and an encapsulation layer TFE.

The base substrate SUB may provide a base surface on which the circuit element layer DP-CL is disposed. The circuit element layer DP-CL may include insulation layers BFL and 10 to 80, the transistors T3 and T6, and connection electrodes CNE11 to CNE13, and CNE2. The insulation layers BFL and 10 to 80 may include a buffer layer BFL, and first to eighth insulation layers 10 to 80 which are disposed on the buffer layer BFL in order from the base substrate SUB. However, the insulation layers included in the circuit element layer DP-CL are not limited thereto, and may vary depending on the configuration of a pixel driving circuit PDC included in the circuit element layer DP-CL and the process of the circuit element layer DP-CL.

The buffer layer BFL may be disposed on the base surface provided by the base substrate SUB. The buffer layer BFL may include at least one inorganic layer. For example, the buffer layer BFL may include at least one of an aluminum oxide, a titanium oxide, a silicon oxide, a silicon nitride, a silicon oxynitride, a zirconium oxide and a hafnium oxide. The buffer layer BFL may improve the coupling force between a semiconductor pattern layer (e.g., a sixth semiconductor pattern SP6) or a conductive pattern layer of the circuit element layer DP-CL disposed on the base substrate SUB, and the base substrate SUB.

Each of the first to eighth insulation layers 10 to 80 may include an inorganic layer and/or an organic layer, and may have a single-layered or multi-layered structure. The inorganic layer may include at least one of an aluminum oxide, a titanium oxide, a silicon oxide, a silicon nitride, a silicon oxynitride, a zirconium oxide and a hafnium oxide. However, the material of the inorganic layer is not limited to the above examples. The organic layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin and a perylene-based resin. However, the material of the organic layer is not limited to the above examples.

A light blocking pattern BML of a light blocking pattern layer may be disposed on the buffer layer BFL. When the buffer layer BFL is omitted, the light blocking pattern BML may be directly disposed on a base layer. The light blocking pattern BML may include molybdenum. The light blocking pattern BML may perform an electrical shielding function. A light blocking pattern BML may prevent an electric potential due to a polarization phenomenon between the insulation layers 10 to 80 disposed on the light blocking pattern BML from affecting first to seventh transistors T1 to T7.

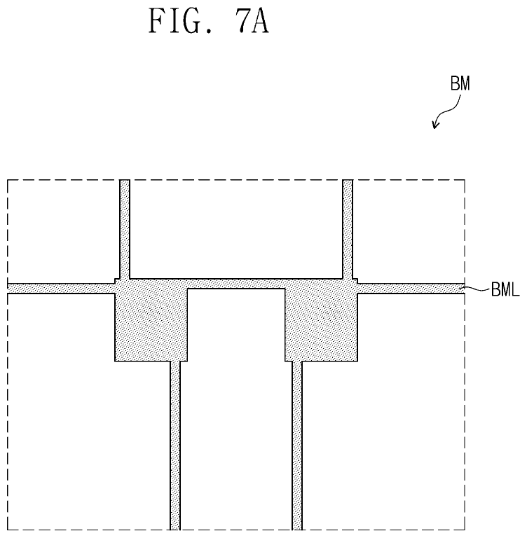

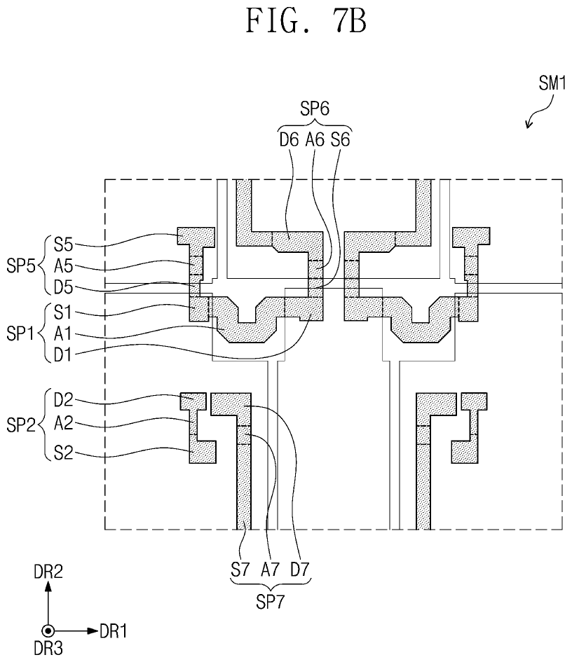

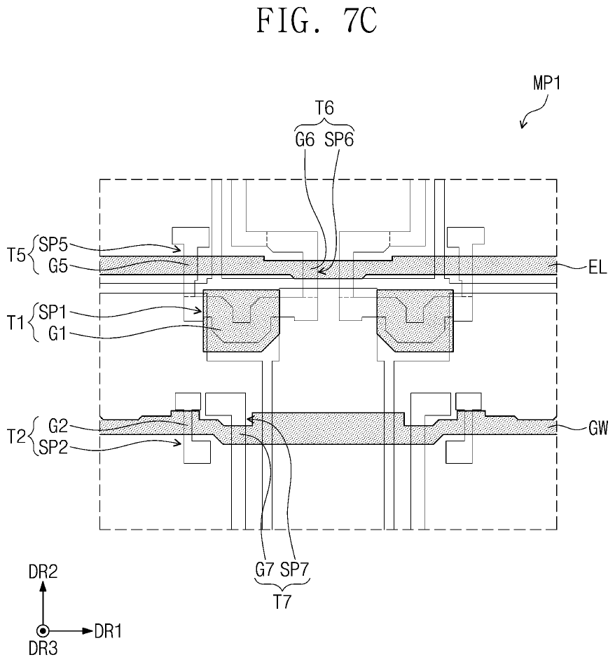

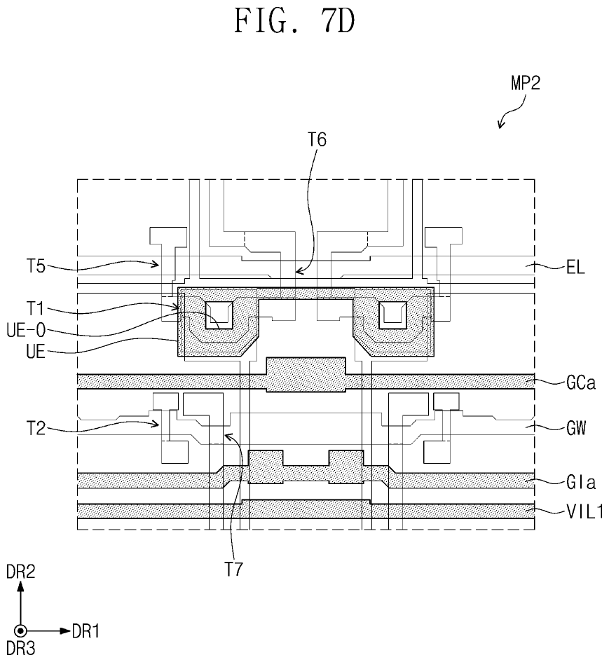

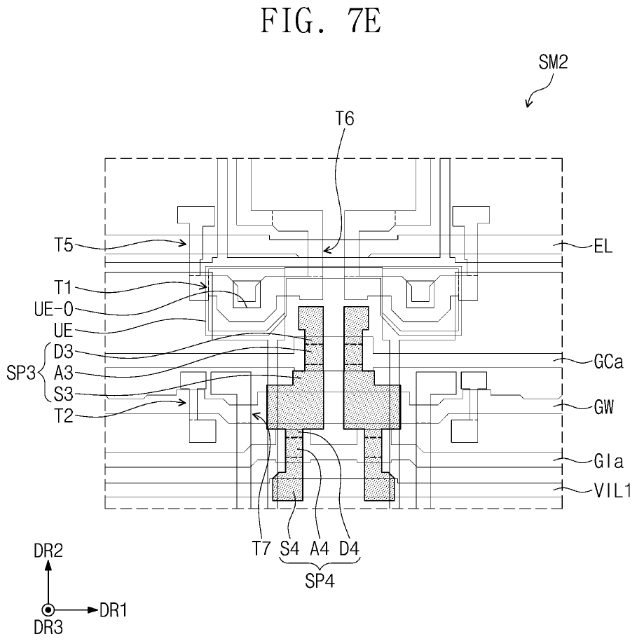

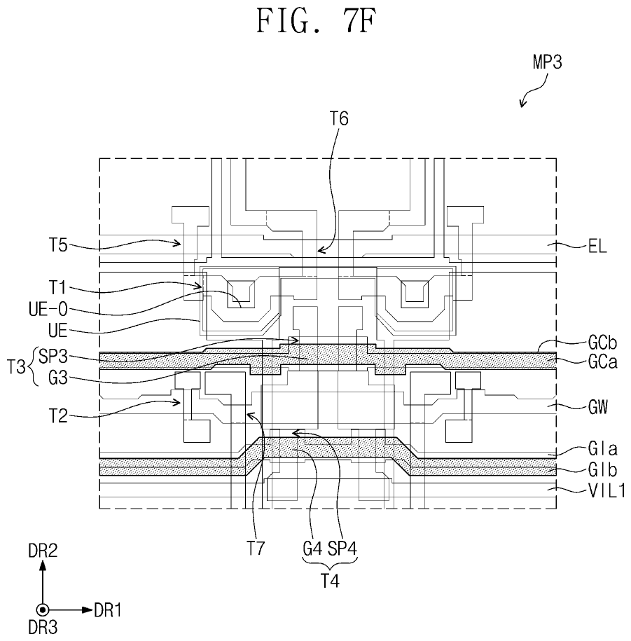

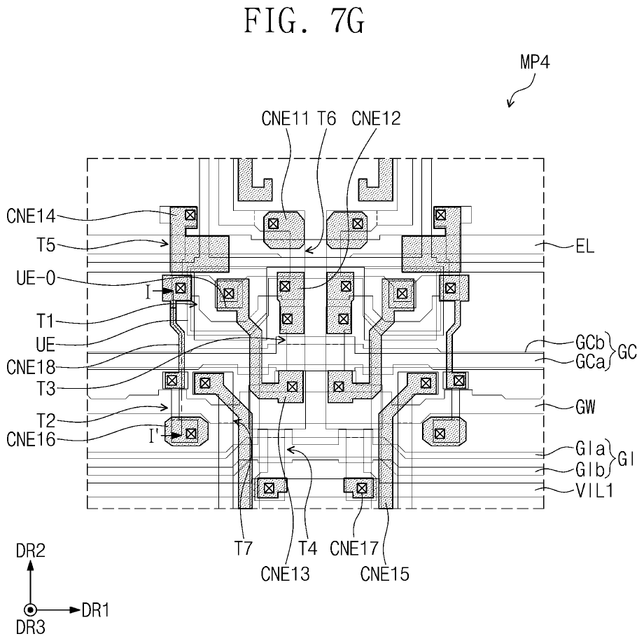

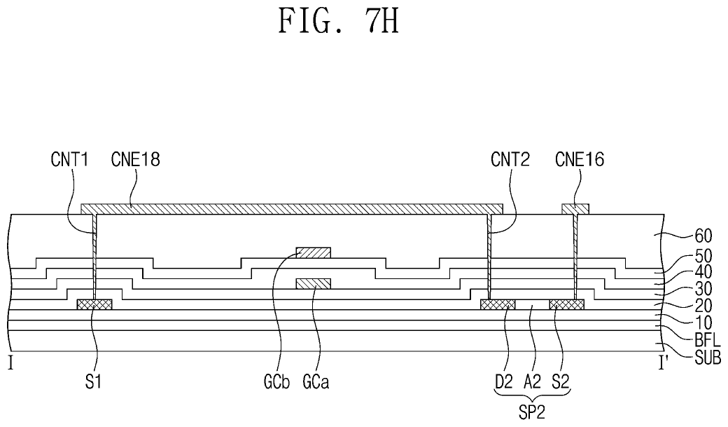

A first semiconductor pattern layer SM1 (see FIG. 7B) may be disposed on the first insulation layer 10. The first semiconductor pattern layer SM1 may include a silicon semiconductor material. For example, the first semiconductor pattern layer may include polysilicon or amorphous silicon. However, if the first semiconductor pattern layer SM1 has semiconductor properties, the materials included in the first semiconductor pattern layer SM1 is not limited to the above examples.

The first semiconductor pattern layer SM1 may include a plurality of regions having different electrical properties depending on whether a region of the first semiconductor pattern layer SM1 is doped or not. The first semiconductor pattern layer SM1 may include a first region having a high conductivity rate and a second region having a low conductivity rate. The first region may be doped with an N-type dopant or a P-type dopant. A P-type transistor may include a doped region which has been doped with the P-type dopant, and an N-type transistor may include a doped region which has been doped with the N-type dopant. The second region may be a non-doped region, or a region doped to a concentration lower than that of the first region.

The conductivity of the first region may be greater than the conductivity of the second region, and the first region may substantially serve as a source and a drain of a transistor. The second region may substantially correspond to a channel (or an active) of a transistor. That is, in the first semiconductor pattern layer, the first region having high conductivity may be a source or a drain of a transistor or a connection signal line, and the second region having low conductivity may be a channel of the transistor.

The sixth semiconductor pattern SP6 of the sixth transistor T6 may be formed from the first semiconductor pattern layer. The sixth semiconductor pattern SP6 may include a sixth source S6, a sixth channel A6, and a sixth drain D6. The sixth source S6 and the sixth drain D6 may be respectively extended in directions opposing each other from the sixth channel A6. That is, the sixth source S6 and the sixth drain D6 may be spaced apart on a plane with the sixth channel A6 interposed therebetween.

The various patterns of the first semiconductor pattern layer SM1 may be in a same layer as each other. As being in a same layer, elements may be formed in a same process and/or include a same material as each other, elements may be respective portions of a same material layer, elements may be on a same layer by forming an interface with a same underlying or overlying layer, etc., without being limited thereto.

The first insulation layer 10 may be disposed on the buffer layer BFL. The first insulation layer 10 may cover the light blocking pattern BML. The second insulation layer 20 may be disposed on the first insulation layer 10. The second insulation layer 20 may cover the first semiconductor pattern layer SM1. For example, the second insulation layer 20 may cover the sixth semiconductor pattern SP6.

A first conductive pattern layer MP1 (see FIG. 7C) may be disposed on the second insulation layer 20. A sixth gate electrode G6 may be formed from the first conductive pattern layer, and the sixth gate electrode G6 may be disposed on the second insulation layer 20. The sixth gate electrode G6 may overlap the sixth channel A6. In an embodiment, the sixth gate electrode G6 may function as a mask in the process of doping the sixth semiconductor pattern SP6.

FIG. 6 exemplarily illustrates that the sixth transistor T6 has a top-gate structure in which the sixth gate electrode G6 is disposed in an upper portion of the sixth semiconductor pattern SP6, but the embodiment is not limited thereto, and the sixth transistor T6 may have a bottom-gate structure in which the sixth gate electrode G6 is disposed in a lower portion of the sixth semiconductor pattern SP6.

Meanwhile, the aforementioned first, second, fifth, and seventh transistors T1, T2, T5, and T7 (see FIG. 5) may be transistors having the same configuration as the sixth transistor T6. For example, semiconductor patterns of the first, second, fifth, and seventh transistors (T1, T2, T5, and T7 (see FIG. 5) may be formed from the first semiconductor pattern layer in the same way as the sixth semiconductor pattern SP6, and gate electrodes of the first, second, fifth, and seventh transistors T1, T2, T5, and T7 (see FIG. 5) may be formed from the first conductive pattern layer in the same way as the sixth gate electrode G6. However, the embodiment of the invention is not necessarily limited thereto.

The third insulation layer 30 may be disposed on the second insulation layer 20. The third insulation layer 30 may cover the first conductive pattern layer MP1. For example, the third insulation layer 30 may cover the sixth gate electrode G6.

A second conductive pattern layer MP2 (see FIG. 7D) may be disposed on the third insulation layer 30. The second conductive pattern layer MP2 may include a scan line SL (see FIG. 6). Although not separately illustrated in FIG. 6, the second conductive pattern layer MP2 may further include an upper electrode UE (see FIG. 7C). The scan line SL may correspond to some of the aforementioned first to third scan lines GWi, GCi, and Gli (see FIG. 5).

The fourth insulation layer 40 may be disposed on the third insulation layer 30. The fourth insulation layer 40 may cover the second conductive pattern layer. For example, the fourth insulation layer 40 may cover the scan line SL.

A second semiconductor pattern layer SM2 (see FIG. 7E) may be disposed on the fourth insulation layer 40. The second semiconductor pattern layer may include a semiconductor material different from that of the first semiconductor pattern layer. For example, the second semiconductor pattern layer may include an oxide semiconductor including a metal oxide. The oxide semiconductor may include a metal oxide of such as zinc (Zn), indium (In), gallium (Ga), tin (Sn), and titanium (Ti), or a mixture of a metal such as zinc (Zn), indium (In), gallium (Ga), tin (Sn), and titanium (Ti) and an oxide thereof. The oxide semiconductor may include an indium-tin oxide (ITO), an indium-gallium-zinc oxide (IGZO), a zinc oxide (ZnO), an indium-zinc oxide (IZO), a zinc-indium oxide (ZIO), an indium oxide (InO), a titanium oxide (TiO), an indium-zinc-tin oxide (IZTO), a zinc-tin oxide (ZTO), and the like. However, the embodiment of the invention is not necessarily limited thereto.

The second semiconductor pattern layer may include a plurality of regions having different electrical properties depending on whether a metal oxide is reduced or not. In the second semiconductor pattern layer, a region in which a metal oxide has been reduced (hereinafter, a reduction region) may have higher conductivity than a region in which the metal oxide has not been reduced (hereinafter, a non-reduction region). The reduction region may substantially serve as a source or a drain of a transistor. The non-reduction region may substantially correspond to a channel (or an active) of a transistor.

Referring to FIG. 6, a third semiconductor pattern SP3 of the third transistor T3 may be formed from the second semiconductor pattern layer. The third semiconductor pattern SP3 may include a third source S3, a third channel A3, and a third drain D3. The third source S3 and the third drain D3 may be respectively extended in directions opposing each other from the third channel A3. That is, the third source S3 and the third drain D3 may be spaced apart on a plane with the third channel A3 interposed therebetween.

The fifth insulation layer 50 may be disposed on the fourth insulation layer 40. The fifth insulation layer 50 may cover the second semiconductor pattern layer. For example, the fifth insulation layer 50 may cover the third semiconductor pattern SP3.

A third conductive pattern layer MP3 (see FIG. 7F) may be disposed on the fifth insulation layer 50. A third gate electrode G3 may be formed from the third conductive pattern layer, and the third gate electrode G3 may be disposed on the fifth insulation layer 50. The third gate electrode G3 may overlap the third channel A3. In an embodiment, the third gate electrode G3 may function as a mask in the process of doping the third semiconductor pattern SP3.

The third semiconductor pattern SP3 may overlap a portion of the scan line SL disposed in a lower portion of the third semiconductor pattern SP3. A portion of the scan line SL overlapping the third semiconductor pattern SP3 may serve as a gate of the third transistor T3 together with the third gate electrode G3. In this case, a third gate of the third transistor T3 may be dually formed to have a sufficient amount of gate charges, and may be switched at a high speed. In addition, since the scan line SL is disposed overlapping the third semiconductor pattern SP3, it is possible to prevent the third semiconductor pattern SP3 from being damaged by light introduced from a lower portion of the display panel DP. However, the above structure of the third transistor T3 is only exemplary, and the embodiment of the invention is not limited thereto.

Meanwhile, the aforementioned fourth transistor T4 (see FIG. 5) may be a transistor having the same structure as the third transistor T3. For example, a semiconductor pattern of the fourth transistor T4 (see FIG. 5) may be formed from the second semiconductor pattern layer in the same way as the third semiconductor pattern SP3, and a gate electrode of the fourth transistor T4 (see FIG. 5) may be formed from the third conductive pattern layer in the same way as the third gate electrode G3. However, the embodiment of the invention is not necessarily limited thereto.

The third semiconductor pattern SP3 of the third transistor T3 and the sixth semiconductor pattern SP6 of the sixth transistor T6 may be disposed on different layers from each other. However, this is only exemplary, and semiconductor patterns of all transistors included in the pixel driving circuit PDC (see FIG. 5) may be disposed on the same layer.

The sixth insulation layer 60 may be disposed on the fifth insulation layer 50. The sixth insulation layer 60 may cover the third conductive pattern layer. For example, the sixth insulation layer 60 may cover the third gate electrode G3.

A fourth conductive pattern layer MP4 (see FIG. 7G) may be disposed on the sixth insulation layer 60. The connection electrodes CNE11 and CNE13 may be formed from the fourth conductive pattern layer. The connection electrodes CNE11 and CNE13 may include 1-1 to 1-3 connection electrodes CNE11 to CNE13. The 1-1 to 1-3 connection electrodes CNE11 to CNE13 may be disposed spaced apart from each other on the same layer 60, which is the sixth insulation layer 60.

The 1-1 connection electrode CNE11 may be connected to the sixth drain D6 of the sixth transistor T6. The 1-1 connection electrode CNE11 may be connected to the sixth drain D6 through a contact-hole penetrating the second to sixth insulation layers 20 to 60.

The 1-2 connection electrode CNE12 may be connected to the sixth source S6 of the sixth transistor T6. The 1-2 connection electrode CNE12 may be connected to the sixth source S6 through a contact-hole penetrating the second to sixth insulation layers 20 to 60.

The 1-2 connection electrode CNE12 may be extended on the plane, and overlap the third drain D3 of the third transistor T3. The 1-2 connection electrode CNE12 may be connected to the third drain D3 through a contact-hole penetrating the fifth and sixth insulation layers 50 and 60. Accordingly, the third semiconductor pattern SP3 of the third transistor T3 and the sixth semiconductor pattern SP6 of the sixth transistor T6 disposed on different layers from each other may be electrically connected to each other through the 1-2 connection electrode CNE12.

The 1-3 connection electrode CNE13 may be connected to the third source S3 of the third transistor T3. The 1-3 connection electrode CNE13 may be connected to the third source S3 through a contact-hole penetrating the fifth and sixth insulation layers 50 and 60.

The seventh insulation layer 70 may be disposed on the sixth insulation layer 60. The seventh insulation layer 70 may cover the fourth conductive pattern layer MP4. For example, the seventh insulation layer 70 may cover the 1-1 to 1-3 connection electrodes CNE11 to CNE13.

A fifth conductive pattern layer may be disposed on the seventh insulation layer 70. A second connection electrode CNE2 of a second connection electrode layer may be formed from the fifth conductive pattern layer. In addition, although not separately illustrated, some of signal lines included in the display panel DP may be formed from the fifth conductive pattern layer. In an embodiment, a data line may be a respective pattern of the fifth conductive pattern layer, without being limited thereto.

The second connection electrode CNE2 may be connected, through a contact-hole passing through the seventh insulation layer 70, to the 1-1 connection electrode CNE11. The second connection electrode CNE2 may be connected to the sixth drain D6 of the sixth transistor T6 through the 1-1 connection electrode CNE11. However, the embodiment of the invention is not limited thereto, and the second connection electrode CNE2 may be omitted, or an additional connection electrode disposed between the second connection electrode CNE2 and the 1-1 connection electrode CNE11 may be further disposed in the circuit element layer DP-CL.

The eighth insulation layer 80 may be disposed on the seventh insulation layer 70. The eighth insulation layer 80 may cover the fifth conductive pattern layer. For example, the eighth insulation layer 80 may cover the second connection electrode CNE2.

At least one of the seventh insulation layer 70 and the eighth insulation layer 80 may include an organic layer. The organic layer may provide a flat surface by covering steps between particles present on the surface of a layer disposed in a lower portion of the organic layer or between components disposed in a lower portion. In addition, the organic layer may relieve stress between components disposed in upper and lower portions.

The display panel DP may include a valley hole (VA-H) defined inside the circuit element layer DP-CL. The valley hole VA-H may be disposed to surround at least one pixel driving circuit PDC (see FIG. 5) on a plane. FIG. 6 exemplarily illustrates a cross-section of a valley hole VA-H disposed to surround two adjacent pixel driving circuits PDC (see FIG. 5) on a plane. As the valley hole VA-H is disposed to surround a specific region inside the circuit element layer DP-CL, an external impact applied on the region surrounded by the valley hole VA-H may be absorbed to minimize the transmission of the external impact to adjacent pixels.

The valley hole VA-H may penetrate at least some of the insulation layers 10 to 80 of the circuit element layer DP-CL. The inside of the valley hole VA-H may be charged with at least some of the second to eighth insulation layers 20 to 80 of the circuit element layer DP-CL. FIG. 6 exemplarily illustrates a valley hole VA-H penetrating the fourth to sixth insulation layers 40 to 60 and being charged with the seventh insulation layer 70. That is, the seventh insulation layer 70 extends through the valley hole VA-H. However, the thickness through which the valley hole VA-H penetrates in the thickness direction of the display panel DP is not limited thereto, and the valley hole VA-H may be formed by penetrating any of the first to eighth insulation layers 10 to 80. This may vary depending on process conditions for forming the valley hole VA-H, and is not limited to any one embodiment.

The display element layer DP-OLED may be disposed on the circuit element layer DP-CL. The display element layer DP-OLED may include a pixel definition film PDL and light emitting elements OLED. Each of the light emitting elements OLED may include a first electrode AE, a light emitting layer EM, and a second electrode CE.

The light emitting elements OLED may include an organic light emitting element, a quantum dot light emitting element, a micro-LED light emitting element, or a nano-LED light emitting element. However, the embodiment of the invention is not limited thereto, and the light emitting elements OLED may include various embodiments as long as light is generated by an electrical signal or the amount of light is controlled.

Each of the light emitting elements OLED may be electrically connected to a transistor of a corresponding pixel drive circuit PDC (see FIG. 5). FIG. 6 exemplarily illustrates that each of the light emitting elements OLED is electrically connected to a corresponding sixth transistor T6.

The first electrodes AE of the light emitting elements OLED may be disposed on the uppermost layer of the circuit element layer DP-CL. For example, the first electrodes AE may be disposed on the eighth insulation layer 80. The first electrodes AE may be disposed spaced apart on the eighth insulation layer 80. Each of the first electrodes AE may be connected, through a contact-hole penetrating the eighth insulation layer 80, to a corresponding second connection electrode CNE2. Each of the first electrodes AE may be electrically connected to the sixth drain D6 through the corresponding second connection electrode CNE2 and the 1-1 connection electrodes CNE11.

The pixel definition film PDL may be disposed on the uppermost layer of the circuit element layer DP-CL. For example, the pixel definition film PDL may be disposed on the eighth insulation layer 80. In the pixel definition film PDL, light emission openings PX-OP overlapping each of the first electrodes AE and exposing a portion of a corresponding first electrode AE to outside the pixel definition film PDL may be defined. In the present embodiment, regions of the first electrodes AE exposed by the light emission openings PX-OP may correspond to light emitting regions PXA. That is, the display region D-DA of the display panel DP may include the light emitting regions PXA. A region in which a solid portion of the pixel definition film PDL is disposed may correspond to a non-light emitting region NPXA. On a plane, the non-light emitting region NPXA surrounds the light emitting regions PXA, and may set the boundary of the light emitting regions PXA within the pixel PX.

The pixel definition film PDL may include a polymer resin. For example, the pixel definition film PDL may include a polyacrylate-based resin or a polyimide-based resin. Without being limited thereto, the pixel definition film PDL may further include an inorganic material.

The pixel definition film PDL may further include a light absorbing material. For example, the pixel definition film PDL may include a black coloring agent such as a black dye or a black pigment. For example, the black coloring agent may include carbon black, a metal such as chromium, or an oxide thereof. However, the embodiment of the invention is not necessarily limited thereto.

The light emitting layer EM may be disposed on the first electrode AE. The light emitting layers EM of the light emitting elements OLED may be disposed corresponding to each of the light emission openings PX-OP, and may be formed as discrete or island shaped light emitting patterns spaced apart on a plane. However, without being limited thereto, the light emitting layers EM of the light emitting elements OLED may be formed as a single film and formed into a common layer across multiple pixels PX. The light emitting layer EM may include an organic light emitting material and/or an inorganic light emitting material. For example, the light emitting layer EM may include a fluorescent material, a phosphorescent material, an organometallic complex light emitting material, or a quantum dot. The light emitting layer EM may emit color light of any one of red, green, and blue colors.

The second electrode CE may be disposed on the light emitting layer EM. The second electrode CE of the light emitting elements OLED may be provided as a common layer of a single body, and may overlap the light emitting regions PXA and the non-light emitting region NPXA. The second electrode CE is commonly disposed in the pixels PX (see FIG. 4), so that a common voltage may be provided.

Meanwhile, the light emitting elements OLED may further include a light emission control layer disposed between the first electrode AE and the second electrode CE. For example, the light emission control layer may include a hole control layer disposed between the first electrode AE and the light emitting layer EM, or an electron control layer disposed between the light emitting layer EM and the second electrode CE. The hole control layer may include a hole injection layer, a hole transport layer, or an electron blocking layer, and the electron control layer may include an electron injection layer, an electron transport layer, or a hole blocking layer.

The encapsulation layer TFE may be disposed on the display element layer DP-OLED. The encapsulation layer TFE may seal the light emitting elements OLED. The encapsulation layer TFE may include at least one thin film of an inorganic film and an organic film. In an embodiment, the encapsulation layer TFE may include inorganic films and an organic film disposed between the inorganic films.

The inorganic film of the encapsulation layer TFE may protect the light emitting elements OLED from moisture and/or oxygen. The inorganic film may include at least one of an aluminum oxide, a titanium oxide, a silicon oxide, a silicon nitride, a silicon oxynitride, a zirconium oxide and a hafnium oxide. However, the material of the inorganic film is not limited to the above examples.

The organic film of the encapsulation layer TFE may protect the light emitting elements OLED from foreign substances such as dust particles. The organic film may include an acrylic resin. However, the material of the organic film is not limited to the above example.

The first driving voltage ELVDD (see FIG. 5) may be applied to the first electrode AE, and the second driving voltage ELVSS (see FIG. 5) may be applied to the second electrode CE. A hole and an electron injected into the light emitting layer EM are combined to form an exciton, and when the exciton transits to a ground state, the light emitting elements OLED may emit light. Since the light emitting elements OLED emit light in response to an applied electrical signal, the display panel DP may display an image through the display region D-DA.

FIG. 7A to FIG. 7G are plan views illustrating a sequential staked structure of patterns constituting the pixel PXij (see FIG. 5). FIG. 7G is a cross-sectional view of some components collectively included in a circuit element layer. FIG. 7H is a cross-sectional view of an embodiment showing a portion corresponding to line I-I′ of FIG. 7G.

The circuit element layer DP-CL (see FIG. 6) may include a semiconductor pattern layer and a conductive pattern layer. Each of the semiconductor pattern layer and the conductive pattern layer may include patterns arranged by a predetermined rule on a plane, and the patterns may constitute the pixel driving circuit PDC (see FIG. 5) and signal lines. FIG. 7A to FIG. 7G exemplarily illustrate plan views corresponding to the pixel driving circuit PDC (see FIG. 5) of adjacent pixels PXij (see FIG. 5).

Referring to FIG. 7A, a light blocking layer BM may be disposed on a base substrate SUB (see FIG. 6). The light blocking layer BM may include a light blocking pattern BML. The light blocking layer BM may include a metal. For example, the light blocking layer BM may include molybdenum. The light blocking layer BM is disposed below a semiconductor pattern included in each of the first to seventh transistors T1 to T7, and thus, may perform the function of blocking light incident from the outside.

Referring to FIG. 7B, the first semiconductor pattern layer SM1 may be disposed on the light blocking layer BM of FIG. 7A. The first semiconductor pattern layer SM1 may include first, second, fifth, sixth, and seventh semiconductor patterns SP1, SP2, SP5, SP6, and SP7. An insulation layer (e.g., the first insulation layer 10 of FIG. 6) may be disposed between the first semiconductor pattern layer SM1 and the light blocking pattern BML. The first semiconductor pattern layer SM1 is disposed on the base substrate SUB (see FIG. 6), and may include a semiconductor material. For example, the first semiconductor pattern layer SM1 may include amorphous silicon or polycrystalline silicon. In the present specification, the first semiconductor pattern layer SM1 including the first, second, fifth, sixth, and seventh semiconductor patterns SP1, SP2, SP5, SP6, and SP7 may be referred to as a “semiconductor pattern layer.”

The first semiconductor pattern layer SM1 may include a plurality of regions having different doping concentrations. In the first semiconductor pattern layer SM1, a region with high conductivity may correspond to a source or a drain of a transistor, and a region with low conductivity may correspond to a channel of the transistor.

The first semiconductor pattern SP1 may include a first source S1, a first drain D1, and a first channel A1. The second semiconductor pattern SP2 may include a second source S2, a second drain D2, and a second channel A2. The fifth semiconductor pattern SP5 may include a fifth source S5, a fifth drain D5, and a fifth channel A5. The sixth semiconductor pattern SP6 may include a sixth source S6, a sixth drain D6, and a sixth channel A6. The seventh semiconductor pattern SP7 may include a seventh source S7, a seventh drain D7, and a seventh channel A7. The first, second, fifth, sixth, and seventh channels A1, A2, A5, A6, and A7 may be disposed between the first, second, fifth, sixth, and seventh sources S1, S2, S5, S6, and S7 and the first, second, fifth, sixth, and seventh drains D1, D2, D5, D6, and D7, respectively.

The first, fifth, sixth, and seventh semiconductor patterns SP1, SP5, SP6, and SP7 constituting the pixel driving circuit PDC (see FIG. 5) may be arranged in the first direction DR1 and the second direction DR2 on a plane. The first, fifth, sixth, and seventh semiconductor patterns SP1, SP5, SP6, and SP7 are formed as a single body, and the second semiconductor pattern SP2 may be spaced apart on a plane from the first, fifth, sixth, and seventh semiconductor patterns SP1, SP5, SP6, and SP7. In the first direction DR1, the first, second, fifth, sixth, and seventh semiconductor patterns SP1, SP2, SP5, SP6, and SP7 may be repeatedly arranged in a symmetrical structure. However, the embodiment of the invention is not limited thereto, and in the first direction DR1, the first, second, fifth, sixth, and seventh semiconductor patterns SP1, SP2, SP5, SP6, and SP7 of the same structure may be repeatedly arranged.

The first semiconductor pattern SP1 may be connected to the fifth semiconductor pattern SP5 and the sixth semiconductor pattern SP6. The first source S1 of the first semiconductor pattern SP1 and the fifth drain D5 of the fifth semiconductor pattern SP5 may be formed as a single body and be electrically connected to each other. A point at which the first semiconductor pattern SP1 and the fifth semiconductor pattern SP5 are connected may correspond to the second node ND2 (see FIG. 5). The first drain DI of the first semiconductor pattern SP1 and the sixth source S6 of the sixth semiconductor pattern SP6 may be formed as a single body and be electrically connected to each other. A point at which the first semiconductor pattern SP1 and the sixth semiconductor pattern SP6 are connected may correspond to the third node ND3 (see FIG. 5).

The second semiconductor pattern SP2 is spaced apart from the first semiconductor pattern SP1 on a plane. The first source S1 of the first semiconductor pattern SP1 and the second drain D2 of the second semiconductor pattern SP2 may be connected on the first semiconductor pattern layer SM1. The first source S1 of the first semiconductor pattern SP1 and the second drain D2 of the second semiconductor pattern SP2 may be connected on the fourth conductive pattern layer MP4 (see FIG. 7G) to be described later. Details of a connection electrode of the first semiconductor pattern SP1 and the second semiconductor pattern SP2 will be described later.

The sixth drain D6 of the sixth semiconductor pattern SP6 may be formed as a single body with the seventh source S7 of the seventh semiconductor pattern SP7 and be electrically connected thereto. A point at which the sixth semiconductor pattern SP6 and the seventh semiconductor pattern SP7 are connected may correspond to the fourth node ND4 (see FIG. 5).

Referring to FIG. 7C, the first conductive pattern layer MP1 may be disposed on the first semiconductor pattern layer SM1 of FIG. 7B. An insulation layer (e.g., the second insulation layer 20 of FIG. 6) may be disposed between the first conductive pattern layer MP1 and the first semiconductor pattern layer SM1 (see, FIG. 7A). The first conductive pattern layer MP1 may include a first gate electrode G1 of a gate conductive layer, a light emission line EL, and a first scan line GW.

The first gate electrode G1 may be disposed on the first semiconductor pattern SP1. The first gate electrode G1 may overlap the first channel A1 on a plane. The first semiconductor pattern SP1 and the first gate electrode G1 may constitute the first transistor T1, and the first gate electrode G1 may correspond to a first gate of the first transistor T1.

The light emission line EL may be extended in the first direction DR1 and overlap the fifth semiconductor pattern SP5 and the sixth semiconductor pattern SP6 on a plane. A portion of the light emission line EL overlapping the fifth semiconductor pattern SP5 may correspond to the fifth gate electrode G5 of the fifth transistor T5, and another portion of the light emission line EL overlapping the sixth semiconductor pattern SP6 may correspond to the sixth gate electrode G6 of the sixth transistor T6. On a plane, the fifth gate electrode G5 may overlap the fifth channel A5 (see FIG. 7B), and the sixth gate electrode G6 may overlap the sixth channel A6 (see FIG. 7A).

The first scan line GW may be extended in the first direction DR1 and be spaced apart from the light emission line EL in the second direction DR2. The first scan line GW may overlap the second semiconductor pattern SP2 and the seventh semiconductor pattern SP7 on a plane. A portion of the first scan line GW may correspond to the second gate electrode G2 of the second transistor T2, and another portion of the first scan line GW overlapping the seventh semiconductor pattern SP7 may correspond to the seventh gate electrode G7 of the seventh transistor T7. On a plane, the second gate electrode G2 may overlap the second channel A2 (see FIG. 7B), and the seventh gate electrode G7 may overlap the seventh channel A7 (see FIG. 7B).

The first conductive pattern layer MP1 may include a metal, an alloy, a conductive metal oxide, a transparent conductive material, or the like. For example, the first conductive pattern layer MP1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), indium zinc oxide (IZO), or the like, but is not particularly limited thereto. The description of the material included in a conductive pattern layer may also be applied to other conductive pattern layers described below.

Referring to FIG. 7D, the second conductive pattern layer MP2 may be disposed on the first conductive pattern layer MP1 of FIG. 7C. An insulation layer (e.g., the third insulation layer 30 of FIG. 6) may be disposed between the second conductive pattern layer MP2 and the first conductive pattern layer MP1 (see, FIG. 7C). The second conductive pattern layer MP2 may include an upper electrode UE, a sub-second scan line GCa, a sub-third scan line G1a, and a first initialization line VIL1.

The upper electrode UE may be disposed overlapping the first gate electrode G1 (see FIG. 7C). The upper electrode UE may form the capacitor CAP (see FIG. 5) together with the first gate electrode G1 (see FIG. 7C) overlapping the upper electrode UE. The upper electrode UE overlapping the first gate electrode G1 (see FIG. 7C) may correspond to a first electrode of the capacitor CAP (see FIG. 5), and the first gate electrode G1 (see FIG. 7C) overlapping the upper electrode UE may correspond to a second electrode of the capacitor CAP (see FIG. 5). The first electrode of the capacitor CAP (see FIG. 5) may be formed as an electrode of a single body with the first gate electrode G1 (see FIG. 7C) and may be electrically connected thereto.

In the upper electrode UE, an opening UE-O penetrating a thickness of the upper electrode UE may be defined. A portion of the first gate electrode G1 (see FIG. 7C) may be exposed to outside the second conductive pattern layer MP2 by the opening UE-O of the upper electrode UE.

The sub-second scan line GCa may be extended in the first direction DR1. The sub-second scan line GCa may correspond to the second scan line GCi (see FIG. 5) to which the compensation scan signal GCSi (see FIG. 5) is applied. In an embodiment, the second scan line GCi (see FIG. 5) may be a line of a dual layer to which the same signal is applied, and the sub-second scan line GCa may be a part thereof. However, the embodiment of the invention is not limited thereto, and the second scan line GCi (see FIG. 5) may be provided as a line of a single layer.

The sub-third scan line G1a may be extended in the first direction DR1, and be spaced from the sub-second scan line GCa in the second direction DR2. The sub-third scan line G1a may correspond to the third scan line Gli (see FIG. 5) to which the initialization scan signal GISi (see FIG. 5) is applied. In an embodiment, the third scan line Gli (see FIG. 5) may be a line of a dual layer to which the same signal is applied, and the sub-third scan line G1a may be a part thereof. However, the embodiment of the invention is not limited thereto, and the third scan line Gli (see FIG. 5) may be provided as a line of a single layer.

The first initialization line VIL1 may be extended in the first direction DR1, and be spaced apart by the sub-second scan line GCa and the sub-third scan line G1a in the second direction DR2. The first initialization voltage Vint1 may be applied to the first initialization line VIL1.

Referring to FIG. 7E, the second semiconductor pattern layer SM2 may be disposed on the second conductive pattern layer MP2 of FIG. 7D. An insulation layer (e.g., the fourth insulation layer 40 of FIG. 6) may be disposed between the second semiconductor pattern layer SM2 and the second conductive pattern layer MP2 (see, FIG. 7D). The second semiconductor pattern layer SM2 may include the second and fourth semiconductor patterns SP3 and SP4. The second semiconductor pattern layer SM2 may include a semiconductor material. For example, the second semiconductor pattern layer SM2 may include a semiconductor material different from that of the first semiconductor pattern layer SM1 (see FIG. 7B). The second semiconductor pattern layer SM2 may include a metal oxide, and the first semiconductor pattern layer SM1 (see FIG. 7B) may include silicon. However, as long as the second semiconductor pattern layer SM2 includes a semiconductor material, the invention is not limited to any one embodiment.

The second semiconductor pattern layer SM2 may include a plurality of regions having different conductivity depending on whether a metal oxide is reduced or not. In the second semiconductor pattern layer SM2, a region with high conductivity may correspond to a source or a drain of a transistor, and a region with low conductivity may correspond to a channel of the transistor.

The third semiconductor pattern SP3 may include a third source S3, a third drain D3, and a third channel A3. The third channel A3 may be disposed between the third source S3 and the third drain D3. The fourth semiconductor pattern SP4 may include a fourth source S4, a fourth drain D4, and a fourth channel A4. The fourth channel A4 may be disposed between the fourth source S4 and the fourth drain D4.

The third and fourth semiconductor patterns SP3 and SP4 constituting the pixel driving circuit PDC (see FIG. 5) may be arranged in the first direction DR1 and the second direction DR2 on a plane. In the first direction DR1, the third and fourth semiconductor patterns SP3 and SP4 may be repeatedly arranged in a symmetrical structure. However, the embodiment of the invention is not limited thereto, and in the first direction DR1, the third and fourth semiconductor patterns SP3 and SP4 of the same structure may be repeatedly arranged.

The third semiconductor pattern SP3 may be connected to the fourth semiconductor pattern SP4. The third source S3 of the third semiconductor pattern SP3 and the fourth drain D4 of the fourth semiconductor pattern SP4 may be formed as a single body and be electrically connected to each other. A point at which the third semiconductor pattern SP3 and the fourth semiconductor pattern SP4 are connected may correspond to the first node ND1 (see FIG. 5).

At least a portion of the third semiconductor pattern SP3 may overlap the first conductive pattern layer MP1 (see FIG. 7B) or the second conductive pattern layer MP2 (see FIG. 7D) on a plane. The third channel A3 of the third semiconductor pattern SP3 may overlap the sub-second scan line GCa disposed in a lower portion. A portion of the sub-second scan line GCa overlapping the third channel A3 may correspond to the third gate. In addition, portions of the first scan line GW and the sub-second scan line GCa overlapping the third semiconductor pattern SP3 may protect the third semiconductor pattern SP3 from light introduced from a lower portion.

At least a portion of the fourth semiconductor pattern SP4 may overlap the first conductive pattern layer MP1 (see FIG. 7C) or the second conductive pattern layer MP2 (see FIG. 7D) on a plane. The fourth channel A4 of the fourth semiconductor pattern SP4 may overlap the sub-third scan line G1a disposed in a lower portion. A portion of the sub-third scan line G1a overlapping the fourth channel A4 may correspond to a fourth gate. In addition, portions of the sub-third scan line G1a and the first initialization line VIL1 overlapping the fourth semiconductor pattern SP4 may protect the fourth semiconductor pattern SP4 from light introduced from a lower portion.

Referring to FIG. 7F, the third conductive pattern layer MP3 may be disposed on the second semiconductor pattern layer SM2 of FIG. 7E. An insulation layer (e.g., the fifth insulation layer 50 of FIG. 6) may be disposed between the third conductive pattern layer MP3 and the second semiconductor pattern layer SM2 (see, FIG. 7E). The third conductive pattern layer MP3 may include a sub-second scan line GCb and a sub-third scan line G1b.

The sub-second scan line GCb may be extended in the first direction DR1. The sub-second scan line GCb may correspond to the second scan line GCi (see FIG. 5) to which the compensation scan signal GCSi (see FIG. 5) is applied. The sub-second scan line GCb of the third conductive pattern layer MP3 and the sub-second scan lines GCa of the second conductive pattern layer MP2 (see FIG. 7D) may overlap each other on a plane. The sub-second scan lines GCa and GCb disposed on different layers from each other may be electrically connected to each other and receive the same signal. That is, in an embodiment, the second scan line GCi (see FIG. 5) may be a line GC of a dual layer to which the same signal is applied, and the sub-second scan line GCb may be a part thereof. However, the embodiment of the invention is not limited thereto, and one of the sub-second scan lines GCa and GCb may be omitted.

The sub-second scan line GCb of the third conductive pattern layer MP3 may overlap the third semiconductor pattern SP3 on a plane. A portion of the sub-second scan line GCb overlapping the third semiconductor pattern SP3 may correspond to the third gate electrode G3 of the third transistor T3. On a plane, the third gate electrode G3 may overlap the third channel A3 (see FIG. 7E). The third channel A3 (see FIG. 7E) may overlap each of the sub-second scan line GCa disposed in a lower portion of the third semiconductor pattern SP3 and the sub-second scan line GCb disposed in an upper portion of the third semiconductor pattern SP3. The third gate of the third transistor T3 may be dually formed to have a sufficient amount of gate charges, and may be switched at a high speed.

The sub-third scan line G1b may be extended in the first direction DR1. The sub-third scan line G1b may correspond to the third scan line Gli (see FIG. 5) to which the initialization scan signal GISi (see FIG. 5) is applied. The sub-third scan line G1b of the third conductive pattern layer MP3 and the sub-third scan line G1a of the second conductive pattern layer MP2 (see FIG. 7D) may overlap each other on a plane. The sub-third scan lines G1a and G1b disposed on different layers from each other may be electrically connected to each other and receive the same signal. That is, in an embodiment, the third scan line Gli (see FIG. 5) may be a line G1 of a dual layer to which the same signal is applied, and the sub-third scan line G1b may be a part thereof. However, the embodiment of the invention is not limited thereto, and one of the sub-third scan lines G1a and G1b may be omitted.

The sub-third scan line G1b of the third conductive pattern layer MP3 may overlap the fourth semiconductor pattern SP4 on a plane. A portion of the sub-third scan line G1b overlapping the fourth semiconductor pattern SP4 may correspond to the fourth gate electrode G4 of the fourth transistor T4. On a plane, the fourth gate electrode G4 may overlap the fourth channel A4. The fourth channel A4 may overlap each of the sub-third scan line G1b disposed in a lower portion of the fourth semiconductor pattern SP4 and the sub-third scan line G1b disposed in an upper portion of the fourth semiconductor pattern SP4. The fourth gate of the fourth transistor T4 may be dually formed to have a sufficient amount of gate charges, and may be switched at a high speed.

Referring to FIG. 7G, the fourth conductive pattern layer MP4 may be disposed on the third conductive pattern layer MP3 of FIG. 7F. An insulation layer (e.g., the sixth insulation layer 60 of FIG. 6) may be disposed between the fourth conductive pattern layer MP4 and the third conductive pattern layer MP3 (see, FIG. 7E). The fourth conductive pattern layer MP4 may include connection electrodes CNE11 to CNE18 spaced apart from each other on the same layer. The connection electrodes CNE11 to CNE18 may be respective portions of a first connection electrode layer.

The connection electrodes CNE11 to CNE18 may each be an electrode which electrically connects components to each other. Each of the connection electrodes CNE11 to CNE18 may overlap the components connected to each other by the connection electrode on a plane. The connection electrodes CNE11 to CNE18 may be connected to a component by extending through at least one insulation layer disposed between the connection electrodes CNE11 to CNE18 and a respective component connected thereto. The connection electrodes CNE11 and CNE18 may include 1-1 to 1-8 connection electrodes CNE11 to CNE18.

The connection electrodes CNE11 to CNE18 includes a metal material. The connection electrodes CNE11 to CNE18 may include metals, alloys, conductive metal oxides, and the like. For example, the connection electrodes CNE11 to CNE18 may include aluminum (Al), alloys containing aluminum, titanium (Ti), alloys containing titanium, silver (Ag), alloys containing silver, molybdenum (Mo), alloys containing molybdenum, aluminum nitride (AlN), tungsten (W), tungsten nitride (WN), copper (Cu), indium tin oxide (ITO), indium zinc oxide (IZO), or the like, but are not particularly limited thereto. For example, the connection electrodes CNE11 to CNE18 may include a three-layered structure of Ti/Al/Ti, but are not limited thereto.

The 1-1 connection electrode CNE11 may overlap the sixth semiconductor pattern SP6 (see FIG. 7B) of the sixth transistor T6. The 1-1 connection electrode CNE11 may be connected to the sixth drain D6 (see FIG. 7B) of the sixth transistor T6 through a contact-hole. The 1-1 connection electrode CNE11 may electrically connect the first electrode AE (see FIG. 6) of the light emitting element OLED (see FIG. 6) to be disposed in an upper portion of the 1-1 connection electrode CNE11 and the sixth transistor T6.

The 1-2 connection electrode CNE12 may overlap each of the first semiconductor pattern SP1 (see FIG. 7B) of the first transistor T1 and the third semiconductor pattern SP3 (see FIG. 7D) of the third transistor T3. The 1-2 connection electrode CNE12 may be connected, through a contact-hole, to the first drain DI (see FIG. 7A) of the first transistor T1 and the third drain D3 (see FIG. 7D) of the third transistor T3. The first drain DI (see FIG. 7B) of the first transistor T1 and the third drain D3 (see FIG. 7E) of the third transistor T3 disposed on different layers from each other may be electrically connected to each other through the 1-2 connection electrode CNE12. A point at which the first transistor TI, the third transistor T3, and the sixth transistor T6 are electrically connected to each other may correspond to the third node ND3 (see FIG. 5).

The 1-3 connection electrode CNE13 may overlap each of the first gate electrode G1 (see FIG. 7B) of the first transistor T1 and the third semiconductor pattern SP3 (see FIG. 7E) of the third transistor T3. The 1-3 connection electrode CNE13 may be connected to the first gate electrode G1 (see FIG. 7C) exposed by the opening UE-O of the upper electrode UE. The 1-3 connection electrode CNE13 may be connected to the third source S3 (see FIG. 7E) of the third transistor T3. The first gate electrode G1 (see FIG. 7C) of the first transistor T1 and the third source S3 (see FIG. 7E) of the third transistor T3 disposed on different layers from each other may be electrically connected to each other through the 1-3 connection electrode CNE13. A point at which the first gate electrode G1 (see FIG. 7B) of the first transistor T1 and the third source S3 (see FIG. 7E) of the third transistor T3 are electrically connected to each other may correspond to the first node NDI (see FIG. 5).

The 1-4 connection electrode CNE14 may overlap each of the upper electrode UE and the fifth semiconductor pattern SP5 (see FIG. 7C) of the fifth transistor T5. The 1-4 connection electrode CNE14 may be connected to the upper electrode UE and the fifth source S5 (see FIG. 7B) of the fifth transistor T5. That is, the 1-4 connection electrode CNE14 may be electrically connected to the upper electrode UE corresponding to the first electrode of the capacitor CAP (see FIG. 5). The 1-4 connection electrode CNE14 may be an electrode connected to the first voltage line VL1 (see FIG. 5) disposed on the 1-4 connection electrode CNE14. That is, the upper electrode UE and the fifth source S5 (see FIG. 7B) of the fifth transistor T5 are electrically connected to the first voltage line VL1 (see FIG. 5) through the 1-4 connection electrode CNE14, and may receive the first driving voltage ELVDD (see FIG. 5).

The 1-5 connection electrode CNE15 may overlap the seventh semiconductor pattern SP7 (see FIG. 7C) of the seventh transistor T7. The 1-5 connection electrode CNE15 may be connected to the seventh source S7 (see FIG. 7B) of the seventh transistor T7. The 1-5 connection electrode CNE15 may be an electrode connected to the second initialization voltage line VIL2 (see FIG. 5) disposed on the 1-5 connection electrode CNE15. That is, the seventh source S7 (see FIG. 7B) of the seventh transistor T7 is electrically connected to the second initialization voltage line VIL2 (see FIG. 5) through the 1-5 connection electrode CNE15, and may receive the second initialization voltage Vint2 (see FIG. 5).

The 1-6 connection electrode CNE16 may overlap the second semiconductor pattern SP2 (see FIG. 7B) of the second transistor T2. The 1-6 connection electrode CNE16 may be connected to the second source S2 (see FIG. 7B) of the second transistor T2. The 1-6 connection electrode CNE16 may be an electrode connected to the data line DLj (see FIG. 5) disposed on the 1-6 connection electrode CNE16. That is, the second source S2 (see FIG. 7B) of the second transistor T2 is electrically connected to the data line DLj (see FIG. 5) through the 1-6 connection electrode CNE16, and may receive the data voltage Vd (see FIG. 5). In an embodiment, the data line DLj of a data conductive layer (not shown in FIG. 7H) may be in a different layer from that of the 1-6 connection electrode CNE16 (e.g., further from the second source S2 than the first connection electrode layer) such that the second source S2 is electrically connected to the data line DLj by the 1-6 connection electrode CNE16. Referring to FIG. 6, for example, the data conductive layer may be defined by a fifth conductive pattern layer on the seventh insulation layer 70, without being limited thereto.

The 1-7 connection electrode CNE17 may overlap the fourth semiconductor pattern SP4 (see FIG. 7E) of the fourth transistor T4. The 1-7 connection electrode CNE17 may be connected to the fourth source S4 (see FIG. 7E) of the fourth transistor T4. The 1-7 connection electrode CNE17 may be an electrode connected to the first initialization line VIL1 through a line or a connection electrode disposed on the 1-7 connection electrode CNE17. That is, the fourth source S4 (see FIG. 7E) of the fourth transistor T4 is electrically connected to the first initialization line VIL1 through the 1-7 connection electrode CNE17, and may receive the first initialization voltage Vint1 (see FIG. 5).

Referring to FIG. 7G and FIG. 7H, the 1-8 connection electrode CNE18 may overlap the first semiconductor pattern SP1 (see FIG. 7B) of the first transistor T1. The 1-8 connection electrode CNE18 may be connected to the first source S1 of the first semiconductor pattern SP1 (see FIG. 7B) by means of a first contact-hole CNT1. The first contact-hole CNT1 may expose at least a portion of the first source S1 by penetrating some of the first to sixth insulation layers 10 to 60. The 1-8 connection electrode CNE18 may overlap the second semiconductor pattern SP2 of the second transistor T2. The 1-8 connecting electrode CNE18 may be connected to the second drain D2 of the second semiconductor pattern SP2 by means of a second contact-hole CNT2. The second contact-hole CNT2 may expose at least a portion of the second drain D2 by penetrating some of the first to sixth insulation layers 10 to 60. The first source S1 of the first semiconductor pattern SP1 (see FIG. 7B) and the second drain D2 of the second semiconductor pattern SP2 may be electrically connected by means of the 1-8 connection electrode CNE18. That is, the 1-8 connection electrode CNE18 may electrically connect the first transistor T1 and the second transistor T2. In the present specification, the 1-8 connection electrode CNE18 electrically connecting the first transistor T1 and the second transistor T2 may be defined as a “connection electrode.”

The 1-8 connection electrode CNE18 includes a metal material. The 1-8 connection electrode CNE18 may be composed of a metal material. A material included in the 1-8 connection electrode CNE18 may be different from a material included in the first semiconductor pattern SP1 (see FIG. 7B) and a material included in the second semiconductor pattern SP2. The 1-8 connection electrode CNE18 may include aluminum (Al) or titanium (Ti). For example, the 1-8 connection electrode CNE18 may include a three-layered structure of Ti/Al/Ti.

The 1-8 connection electrode CNE18 may include a material with a low clastic modulus. The 1-8 connection electrode CNE18 may include a material having a relatively low clastic modulus compared to a material included in the first semiconductor pattern SP1 (see FIG. 7B) and a material included in the second semiconductor pattern SP2. The 1-8 connection electrode CNE18 may include a material having a relatively low elastic modulus compared to polysilicon. The clastic modulus of the 1-8 connection electrode CNE18 may be about 50 gigapascals (GPa) to about 130 GPa. For example, the clastic modulus of the 1-8 connection electrode CNE18 may be about 70 GPa to about 90 GPa. Since the clastic modulus of the 1-8 connection electrode CNE18 is relatively low, an external impact and stress applied to the second transistor T2 disposed in a region adjacent to the 1-8 connection electrode CNE18 may be reduced.

Meanwhile, the shape and the arrangement of pattern layers constituting a pixel illustrated in FIG. 7A to FIG. 7H are only exemplary, and are not necessarily limited thereto.

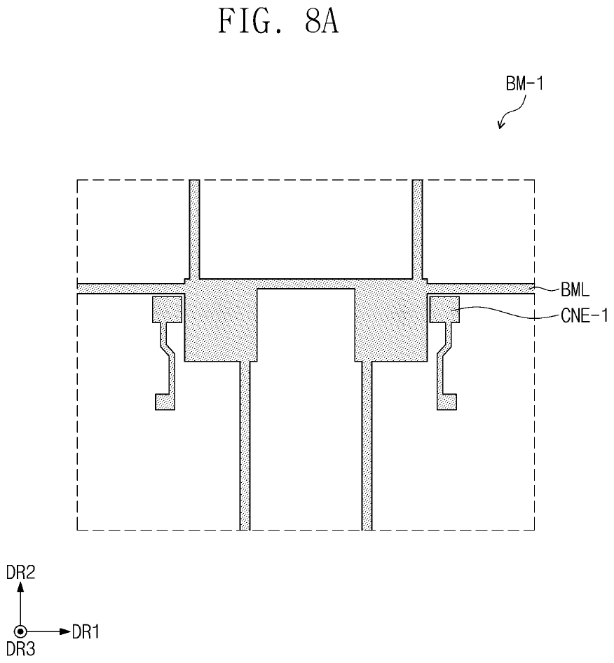

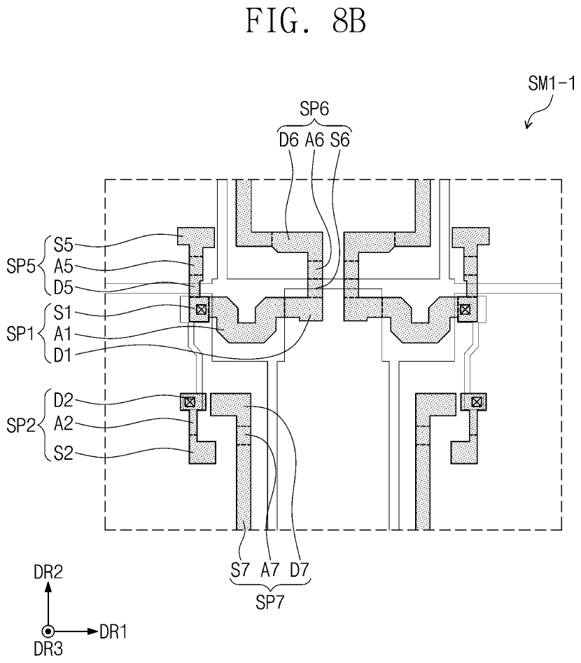

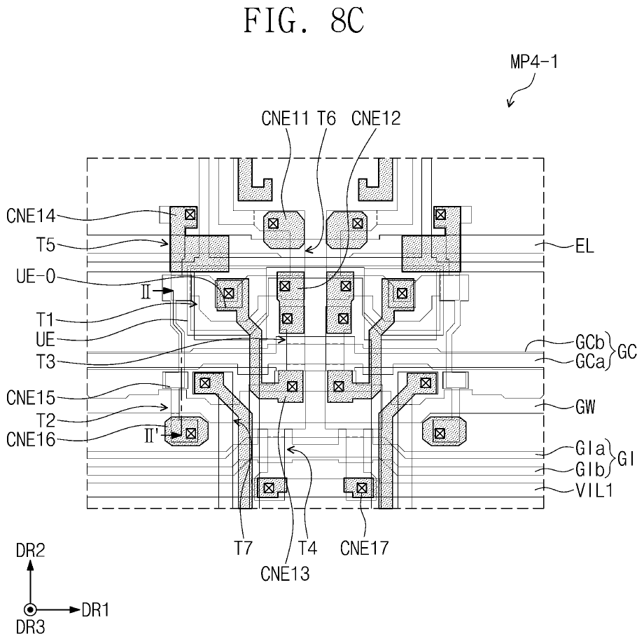

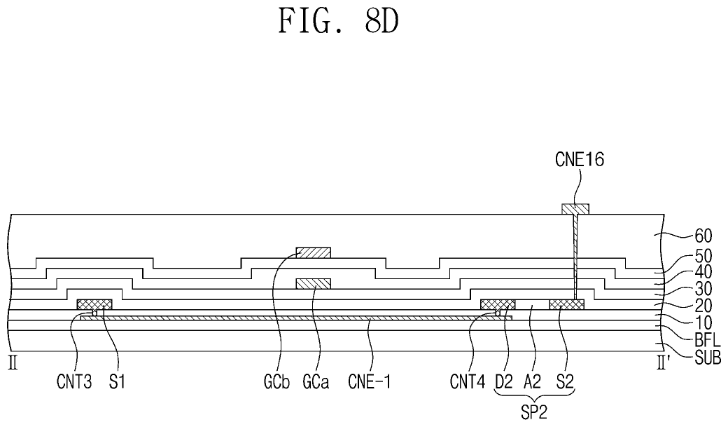

FIG. 8A to FIG. 8C are plan views illustrating a portion of a sequential stacked structure of patterns constituting a pixel PXij (see FIG. 5) according to another embodiment of the invention. FIG. 8A illustrates a plan view of a light blocking layer BM−1 according to another embodiment of the invention, FIG. 8B illustrates a first semiconductor pattern layer SM1-1 according to another embodiment of the invention, and FIG. 8C shows a fourth conductive pattern layer MP4-1 according to another embodiment of the invention. FIG. 8D is a cross-sectional view of some components included in a circuit element layer DP-CL according to another embodiment of the invention. FIG. 8D is a cross-sectional view of an embodiment showing a portion corresponding to line II-II′ of FIG. 8C.

Referring to FIG. 8A, FIG. 8B, and FIG. 8D, the light blocking layer BM−1 may include a light blocking pattern BML and a lower connection electrode CNE−1. The first semiconductor pattern layer SM1-1 may include first, second, fifth, sixth, and seventh semiconductor patterns SP1, SP2, SP5, SP6, and SP7.

The lower connection electrode CNE-1 may overlap the first semiconductor pattern SP1 of the first transistor T1. The lower connection electrode CNE-1 may be connected to the first source S1 of the first semiconductor pattern SP1 by means of a third contact-hole CNT3. The third contact-hole CNT3 may expose at least a portion of the first source S1 by penetrating a portion of the buffer layer BFL. The lower connection electrode CNE-1 may overlap the second semiconductor pattern SP2 of the second transistor T2. The lower connection electrode CNE-1 may be connected to the second drain D2 of the second semiconductor pattern SP2 by means of a fourth contact-hole CNT4. The fourth contact-hole CNT4 may expose at least a portion of the second drain D2 by penetrating a portion of the buffer layer BFL. The lower connection electrode CNE-1 may be an electrode electrically connecting between the first source S1 of the first semiconductor pattern SP1 and the second drain D2 of the second semiconductor pattern SP2. Accordingly, the first transistor T1 and the second transistor T2 may be electrically connected by means of the lower connection electrode CNE-1. In the present specification, the lower connection electrode CNE-1 electrically connecting the first transistor T1 and the second transistor T2 may be defined as a “connection electrode.”

The lower connection electrode CNE-1 includes a metal material. The lower connection electrode CNE-1 may be composed of a metal material. A material included in the lower connection electrode CNE-1 may be different from a material included in the first semiconductor pattern SP1 and a material included in the second semiconductor pattern SP2. For example, the lower connection electrode CNE-1 may include molybdenum.

Referring to FIG. 8C, the fourth conductive pattern layer MP4-1 may include connection electrodes CNE11 to CNE17 (omitting CNE18) spaced apart from each other on the same layer. The connection electrodes CNE11 to CNE17 may each be an electrode which electrically connects between components connected to the connection electrode.

Depending on the configuration of transistors and a pixel driving circuit PDC, when some transistors are damaged, defects such as a light spot or a dark spot may occur. For example, when a second transistor T2 or a third transistor T3 is damaged, a light emitting element OLED continuously emits light, so that a defect in which a bright spot is visually recognized may occur. In a first semiconductor pattern layer SM1 according to an embodiment, a signal line or the like is not disposed in a region adjacent to the semiconductor pattern of the second transistor T2, so that stress applied to the region adjacent to the semiconductor pattern of the second transistor T2 is relieved, thereby preventing damage to the second transistor T2. In addition, since a connection electrode of the first transistor T1 and the second transistor T2 includes a metal instead of polysilicon, the impact resistance of the region adjacent to the semiconductor pattern of the second transistor T2 may be improved. Accordingly, the display panel DP according to an embodiment of the invention may prevent transistors from being damaged by an external shock and stress.

Referring to FIG. 7H, for example, the connection electrode (CNE18) is a portion of a metal layer (MP4) below the semiconductor pattern layer (SM1). Referring to FIG. 8D, for example, the connection electrode (CNE-1) is a portion of a metal layer (BM−1) above the semiconductor pattern layer (SM1). In embodiments, a plurality of material layers (BM, SM1, MP1, MP2, SM2, MP3, MP4, various insulation layers, the data conductive layer, etc. is on the buffer layer BFL. The semiconductor pattern layer (SM1) and the connection electrode (CNE18 or CNE-1) are defined by different material layers among the plurality of material layers on the buffer layer BFL.

A display panel DP of an embodiment of the present invention includes a connection electrode, and thus, may reduce or effectively prevent propagation of cracks between inorganic layers in a circuit element layer caused by external impacts or stress. As a result, the display panel DP may have improved impact resistance and improved reliability.

Although the present invention has been described with reference to embodiments of the present invention, it will be understood by those skilled in the art that various modifications and changes in form and details may be made therein without departing from the spirit and scope of the present invention as set forth in the following claims.

Accordingly, the technical scope of the present invention is not intended to be limited to the contents set forth in the detailed description of the specification, but is intended to be defined by the appended claims.

What is claimed is:

1. A display panel comprising:
a light emitting element; and
a pixel circuit electrically connected to the light emitting element, wherein the pixel circuit includes:
a semiconductor pattern layer defining:
a first semiconductor pattern electrically connected to the light emitting element, and
a second semiconductor pattern which is spaced apart from the first semiconductor pattern along the semiconductor pattern layer;
a data line on the semiconductor pattern layer and electrically connected to the second semiconductor pattern; and
a connection electrode electrically connecting the first semiconductor pattern and the second semiconductor pattern which are spaced apart from each other, to each other,
wherein along a thickness direction of the display panel, the connection electrode is a portion of a metal layer below the semiconductor pattern layer or a portion of a metal layer above the semiconductor pattern layer.

2. The display panel of claim 1, wherein a material of the connection electrode is different from a material of the semiconductor pattern layer.

3. The display panel of claim 2, wherein:
the first semiconductor pattern and the second semiconductor pattern each comprise polysilicon; and
the connection electrode comprises a metal material.

4. The display panel of claim 1, wherein:
the first semiconductor pattern comprises a first source region, a first drain region, and a first channel region between the first source region and the first drain region; and
the second semiconductor pattern comprises a second source region, a second drain region, and a second channel region between the second source region and the second drain region.

5. The display panel of claim 4, wherein the connection electrode is electrically connected to the first semiconductor pattern at the first source region thereof and to the second semiconductor pattern at the second drain region thereof.

6. The display panel of claim 4, wherein:
the first semiconductor pattern is electrically connected to the light emitting element at the first drain region; and
the second semiconductor pattern is electrically connected to the data line at the second source region.

7. The display panel of claim 4, wherein the pixel circuit further includes:
a driving transistor including the first semiconductor pattern and a first gate electrode which overlaps the first channel region of the first semiconductor pattern, and
a switching transistor including the second semiconductor pattern and a second gate electrode which overlaps the second channel region of the second semiconductor pattern.

8. The display panel of claim 1, wherein along the thickness direction of the display panel:
the pixel circuit further includes:
a first insulation layer below the semiconductor pattern layer, and
a buffer layer below the first insulation layer, and
the connection electrode is between the first insulation layer and the buffer layer.

9. The display panel of claim 8, wherein the pixel circuit further includes a light blocking layer defining the connection electrode and a light blocking pattern which is spaced apart from the connection electrode along the light blocking layer.

10. The display panel of claim 8, wherein the connection electrode comprises molybdenum.

11. The display panel of claim 8, wherein within the pixel circuit:
a first contact-hole and a second contact-hole are defined in the buffer layer,
the first semiconductor pattern and the connection electrode are electrically connected to each other at the first contact-hole, and
the second semiconductor pattern and the connection electrode are electrically connected to each other at the second contact-hole.

12. The display panel of claim 1, wherein the pixel circuit further includes:
an insulation layer covering the semiconductor pattern layer, and
the connection electrode on the insulation layer covering the semiconductor pattern layer.

13. The display panel of claim 12, wherein within the pixel circuit:
a first contact-hole and a second contact-hole are defined in the insulation layer,
the connection electrode and the first semiconductor pattern are electrically connected to each other at the first contact-hole, and
the connection electrode and the second semiconductor pattern are electrically connected to each other at the second contact-hole.

14. The display panel of claim 12, wherein the connection electrode comprises aluminum or titanium.

15. The display panel of claim 12, wherein the elastic modulus of the connection electrode is about 50 gigapascals to about 130 gigapascals.

16. The display panel of claim 12, wherein the elastic modulus of the connection electrode is lower than the elastic modulus of the semiconductor pattern layer.

17. The display panel of claim 1, wherein the first semiconductor pattern of the semiconductor pattern layer extends to define a third semiconductor pattern which is spaced apart from the second semiconductor pattern along the semiconductor pattern layer.

18. The display panel of claim 17, wherein
the light emitting element comprises a first electrode, an organic layer on the first electrode and including a light emitting layer, and a second electrode on the organic layer, and
the third semiconductor pattern is electrically connected to the light emitting element at the first electrode thereof.

19. A display panel comprising:
a light emitting element; and
a pixel circuit electrically connected to the light emitting element, wherein the pixel circuit includes:
a buffer layer;
a connection electrode;
a first insulation layer on the buffer layer;
a semiconductor pattern layer on the first insulation layer and defining:
a first semiconductor pattern of a first transistor, and
a second semiconductor pattern of a second transistor which is spaced apart from the first semiconductor pattern, the second semiconductor pattern electrically connected to the first semiconductor pattern by the connection electrode;
a second insulation layer on the first insulation layer and covering the semiconductor pattern layer;
a gate conductive layer on the second insulation layer and defining a first gate electrode of the first transistor and a second gate electrode of the second transistor which is spaced apart from the first gate electrode; and
a third insulation layer on the second insulation layer and covering the gate conductive layer,
wherein:
the first semiconductor pattern and the second semiconductor pattern each includes polysilicon; and
the connection electrode includes a metal material.

20. The display panel of claim 19, further comprising a plurality of material layers on the buffer layer,
wherein the semiconductor pattern layer and the connection electrode are defined by different material layers among the plurality of material layers on the buffer layer.
